(19) United States
(12) Patent Application Publication
(10) Pub. No.: US 2007/0030014 A1
(43) Pub. Date: Feb. 8, 2007

(54) Multi-jack cable adapter for multi-cable testing and alien cross-talk cable testing

(76) Inventors: Harshang Pandya, Singapore (SG); Xing Zhu, Singapore (SG)

Correspondence Address: AGILENT TECHNOLOGIES INC., INTELLECTUAL PROPERTY ADMINISTRATION, M/S DU404, P.O. BOX 7599, LOVELAND, CO, 80537-0599, US

(21) Appl. No.: 11/316,197

(22) Filed: Dec. 22, 2005

Related U.S. Application Data
(63) Continuation-in-part of application No. 11/196,113, filed on Aug. 3, 2005, now Pat. No. 7,081,763.

(51) Int. Cl. G01R 23/20

(52) U.S. Cl. 324/626

(57) ABSTRACT

A cable testing system employs a cable tester and a multi-jack cable adapter, which includes a switch matrix and a switch controller. In operation, the switch matrix is in electrical communication with the cable tester and a plurality of cables to establish a plurality of signal paths between the cable tester and the plurality of cables, and the switch controller is in electrical communication with the switch matrix and the cable tester to control a switching of each signal path by the switch matrix between an activated state and a deactivated state as commanded by the cable tester.

### CROSS-REFERENCE TO RELATED APPLICATION

This application is a continuation-in-part of U.S. patent application Ser. No. 11/196,113, entitled “TEST SYSTEM AND METHOD FOR FIELD MEASUREMENT OF ALIEN CROSS-TALK” and filed Aug. 3, 2005.

### BACKGROUND OF THE INVENTION

Multiple-cable testing typically involves an operator connecting a local end of a cable to a cable tester at a local site and then connecting a remote end of a cable to a cable tester at a remote site. Upon testing the cable at the local site, the operator disconnects the local end of the cable from the local cable tester and then disconnects the remote end of the cable from the remote cable tester to thereby facilitate a testing of another cable. This manner of performing multiple casting testing can be unacceptably time consuming in dependence on the distance between the local site and the remote site and the number of cables under test.

Furthermore, alien cross-talk between cables reduces the operational bandwidth of a cabling channel because of an increased level of cross-talk noise decreasing the overall signal-to-noise ratio. Thus, with the recent deployment of high-speed networking, the measurement of alien cross-talk has become an important issue.

A powersum alien cross-talk measurement typically involves a “victim” cable having four (4) wire pairs being tested with n number of “disturber” cables, each having four (4) wire pairs. One specific approach is to test the “victim” cable with only one of the “disturber” cables at a time in the context of separately measuring powersum alien near end cross-talk (“PSANEXT”) and powersum alien far end cross-talk (“PSAFEXT”) for each wire pair. Drawbacks to this approach is it is extremely time consuming and error-prone.

Another specific approach is to enclose the “victim” cable with n number of “disturber” cables that are excited with white noise. Drawbacks to this approach is its complexity and power consumption with an inaccurate measurement.

Thus, a need exists to provide a solution for multi-cable testing and alien cross-talk testing in a complete, convenient, cost effective and expedient manner.

### SUMMARY OF THE INVENTION

The present invention provides a cable testing system that is complete, convenient, cost effective and expedient. In particular, the cable testing system is adaptive to perform multiple-cable testing and/or an alien cross-talk cable testing.

A first form of the present invention is a cable testing system comprising a cable tester and a multi-jack cable adapter including a switch matrix and a switch controller. In operation, the switch matrix is in electrical communication with the cable tester and a plurality of cables to establish a plurality of signal paths between the cable tester and the plurality of cables, and the switch controller is in electrical communication with the switch matrix and the cable tester to control a switching of each signal path by the switch matrix between an activated state and a deactivated state as commanded by the cable tester.

A second form of the present invention is a multi-jack cable adapter comprising a switch matrix and a switch controller. In operation, the switch matrix is in electrical communication with a cable tester and a plurality of cables to establish a plurality of signal paths between the cable tester and the plurality of cables, and the switch controller is in electrical communication with the switch matrix and the cable tester to control a switching of each signal path by the switch matrix between an activated state and a deactivated state as commanded by the cable tester.

The third form of the present invention is a cable testing method for testing a plurality of cables. The cable testing method comprising providing a switch matrix establishing a plurality of signal paths between a cable tester and a plurality of cables, and controlling a switching of each signal path by the switch matrix between an activated state and a deactivated state as commanded by the cable tester.

The aforementioned forms and other forms as well as objects and advantages of the present invention will become further apparent from the following detailed description of the various embodiments of the present invention read in conjunction with the accompanying drawings. The detailed description and drawings are merely illustrative of the invention rather than limiting, the scope of the present invention being defined by the appended claims and equivalents thereof.

### BRIEF DESCRIPTION OF THE DRAWINGS

FIG. 1 illustrates a first embodiment of an alien cross-talk test system in accordance with the present invention;

FIG. 2 illustrates one embodiment of a alien cross-talk test signal unit illustrated in FIG. 1 in accordance with the present invention;

FIG. 3 illustrates one embodiment of the alien cross-talk test signal unit illustrated in FIG. 2 in accordance with the present invention;

FIGS. 4 and 5 illustrate one embodiment of a switch illustrated in FIG. 3 in accordance with the present invention;

FIG. 6 illustrates one embodiment of a keypad/LED indicator illustrated in FIG. 3 in accordance with the present invention;

FIG. 7 illustrates one embodiment of a working mode diagram of an alien cross-talk test signal unit in accordance with the present invention;

FIG. 8 illustrates one embodiment of the alien cross-talk test system illustrated in FIG. 1 in accordance with the present invention;

FIG. 9 illustrates a flowchart representative of one embodiment of a RF test signal generation method in accordance with the present invention;

FIG. 10 illustrates a flowchart representative of one embodiment of a RF test signal termination method in accordance with the present invention;

FIG. 11 illustrates a flowchart representative of one embodiment of an alien cross-talk signal termination method in accordance with the present invention;

FIG. 12 illustrates a flowchart representative of a first embodiment of an alien cross-talk measurement method in accordance with the present invention;

FIG. 13 illustrates an exemplary near end PSANEXT of the alien cross-talk system illustrated in FIG. 8 in accordance with the present invention;

FIG. 14 illustrates an exemplary far end PSAFEXT of the alien cross-talk system illustrated in FIG. 8 in accordance with the present invention;

FIG. 15 illustrates an exemplary far end PSANEXT of the alien cross-talk system illustrated in FIG. 8 in accordance with the present invention;

FIG. 16 illustrates an exemplary near end PSAFEXT of the alien cross-talk system illustrated in FIG. 8 in accordance with the present invention;

FIG. 17 illustrates a flowchart representative of one embodiment of a manual transmit mode selection method in accordance with the present invention;

FIG. 18 illustrates a flowchart representative of one embodiment of an automatic listen mode selection method in accordance with the present invention;

FIG. 19 illustrates a flowchart representative of one embodiment of a manual listen mode selection method in accordance with the present invention;

FIG. 20 illustrates a flowchart representative of one embodiment of an automatic transmit mode selection method in accordance with the present invention;

FIG. 21 illustrates a flowchart representative of one embodiment of a RF frequency sweep testing signal transmission method in accordance with the present invention;

FIG. 22 illustrates a flowchart representative of one embodiment of RF frequency sweep measurement method in accordance with the present invention;

FIG. 23 illustrates one embodiment of a RF frequency sweep test signal in accordance with the present invention;

FIG. 24 illustrates one embodiment of a RF frequency measurement sweep in accordance with the present invention;

FIG. 25 illustrates an exemplary cross-talk between the RF frequency sweep test signal illustrated in FIG. 23 and the RF frequency measurement sweep illustrated in FIG. 24;

FIG. 26 illustrates a flowchart representative of one embodiment of a powersum alien cross-talk determination method in accordance with the present invention;

FIGS. 27-31 illustrates exemplary embodiments of a switchable signal path in accordance with the present invention;

FIG. 32 illustrates a second embodiment of a cable testing system in accordance with the present invention;

FIG. 33 illustrates one embodiment of a switch matrix in accordance with the present invention;

FIGS. 34-37 illustrate one embodiment of a single pole,. tripe throw switch in accordance with the present invention:

FIGS. 38-40 illustrate one embodiment of a single pole, double throw switch in accordance with the present invention;

FIG. 41 illustrates one embodiment of the switch matrix illustrated in FIG. 33 in accordance with the present invention;

FIG. 42 illustrates a first embodiment of the multi-cable test system illustrated in FIG. 31 in accordance with the present invention;

FIG. 43 illustrates a flowchart representative of a first embodiment of a multi-cable testing method in accordance with the present invention;

FIG. 44 illustrates a second embodiment of the multi-cable test system illustrated in FIG. 31 in accordance with the present invention;

FIG. 45 illustrates a flowchart representative of a second embodiment of a multi-cable testing method in accordance with the present invention;

FIG. 46 illustrates a second embodiment of the alien cross-talk system in accordance with the present invention;

FIG. 47 illustrates a flowchart representative of a second embodiment of an alien cross-talk testing method in accordance with the present invention;

FIG. 48 illustrates an exemplary near end ANEXT of the alien cross-talk system illustrated in FIG. 46 in accordance with the present invention;

FIG. 49 illustrates an exemplary far end ANEXT of the alien cross-talk system illustrated in FIG. 46 in accordance with the present invention;

FIG. 50 illustrates an exemplary near end AFEXT of the alien cross-talk system illustrated in FIG. 46 in accordance with the present invention;

FIG. 51 illustrates an exemplary far end AFEXT of the alien cross-talk system illustrated in FIG. 46 in accordance with the present invention;

FIG. 52 illustrates a third embodiment of the alien cross-talk system in accordance with the present invention;

FIG. 53 illustrates a flowchart representative of a third embodiment of an alien cross-talk testing method in accordance with the present invention;

FIG. 54 illustrates an exemplary ANEXT of the alien cross-talk system illustrated in FIG. 52 in accordance with the present invention;

FIGS. 55 and 56 illustrate flowcharts representative of a fourth embodiment of an alien cross-talk testing method in accordance with the present invention; and

FIG. 57 illustrates an exemplary PSAFEXT of the alien cross-talk system illustrated in FIG. 52 in accordance with the present invention;

### DETAILED DESCRIPTION

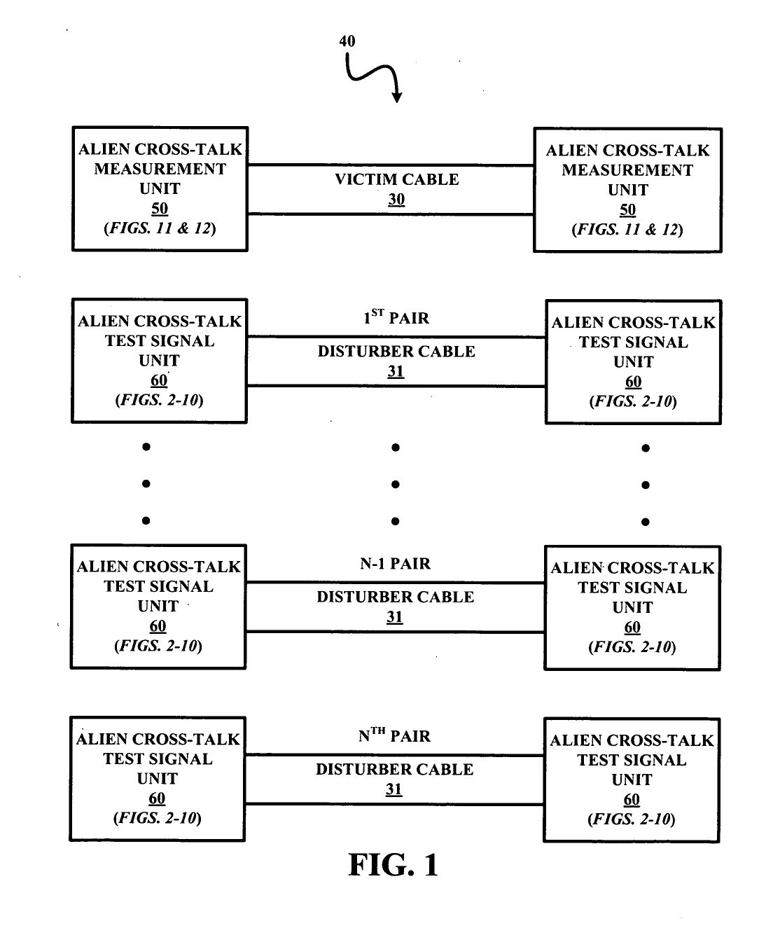

FIG. 1 illustrates an alien cross-talk test system 40 of the present invention employing a pair of alien cross-talk measurement units 50 and a N number of pairs of alien cross-talk test signal units 60, where N≧1. Generally, cross-talk measurement units 50 are structurally configured to be connected to opposing ends of a victim cable 30 having an M number of wire pairs, and each pair of alien cross-talk test signal units 60 are structurally configured to be connected to opposing ends of a disturber cable 31 having M number of wire pairs, where M≧1. Each pair of cross-talk generators 60 are further structurally configured to generate an alien cross-talk test signal on one end of connected disturber cable 31 and to terminate the alien cross-talk test signal on the other end of the disturber cable 31. Cross-talk measurement units 50 are further structurally configured to measure an alien cross-talk signal on one end of victim cable 30, and to terminate the alien cross-talk signal on the other end of the victim cable 30. The alien cross-talk signal on victim cable 30 is generated by an alien cross-talking coupling between victim cable 30 and a disturber cable 31 as an alien cross-talk test signal is being transmitted between corresponding alien cross-talk test signal units 60.

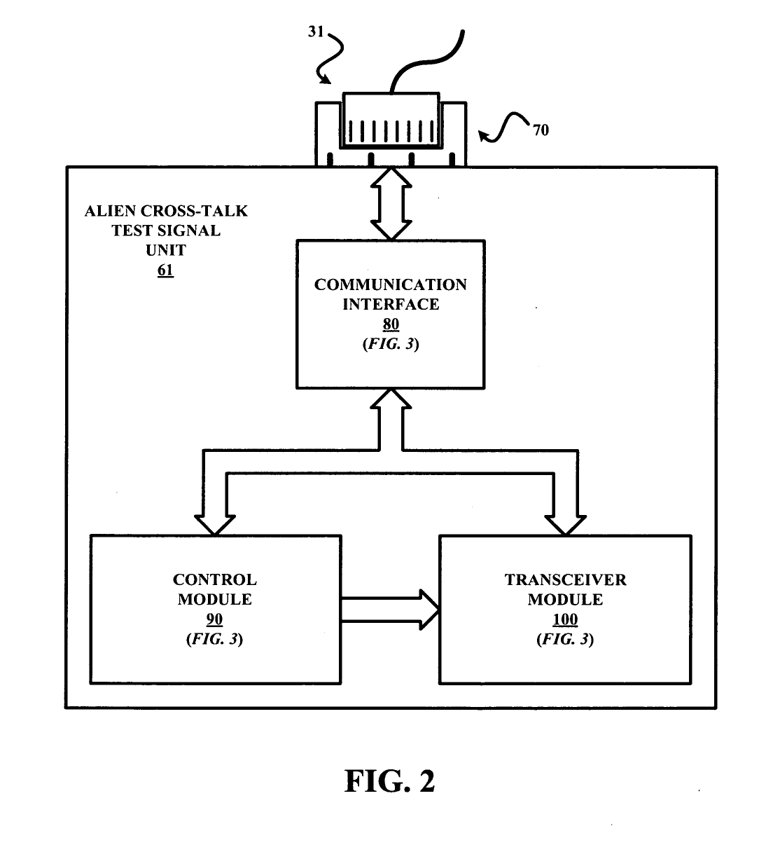

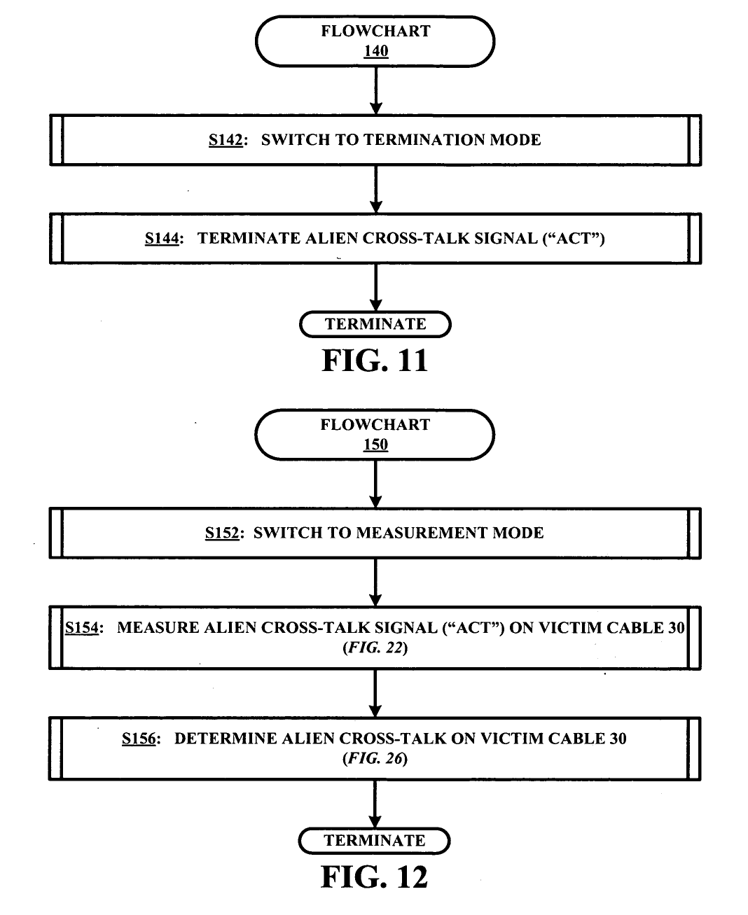

In practice, the present invention does not impose any limitations or any restrictions to the structural embodiments of alien cross-talk measurement units 50 and alien cross-talk test signal units 60. Thus, the following descriptions of various structural embodiments of alien cross-talk measurement units 50 connected with FIGS. 11 and 12, and various structural embodiments of alien cross-talk test signal units 60 connected with FIGS. 2-10 neither limit nor restrict a scope of structural embodiments of alien cross-talk measurement units 50 and structural embodiments of alien cross-talk test signal units 60.

FIG. 2 illustrates a general embodiment 61 of alien cross-talk test signal unit 60 (FIG. 1). Alien cross-talk test signal unit 61 employs a cable jack 70 (e.g., a RJ-45 jack), a communication interface 80, a control module 90 and a transceiver module 100. Cable jack 70 is structurally configured to connect test unit 61 to one end of a disturber cable 31 having four (4) wire pairs (i.e., M=4) as shown. Communication interface 80 is structurally configured to transmit and receive alien cross-talk test signals with another test unit 61 connected to an opposing end of disturber cable 31 (not shown). In an alternative embodiment, communication interface 80 is further structurally configured to exchange logical commands on behalf of control module 90 with another test unit 61 connected to an opposing end of disturber cable 31 Transceiver module 100 is structurally configured to selectively transmit an alien cross-talk test signal via interface 80 to another test unit 61 connected to the opposing end of disturber cable 31 or terminate an alien cross-talk test signal received via interface 80 from another test unit 61 connected to the opposing end of disturber cable 31. Control module 90 is structurally configured to selectively set transceiver module 100 as an alien cross-talk test signal transmitter or an alien cross-talk test signal terminator based on commands received by control module 90. In one embodiment, control module 90 is further structurally configured to manually receive the commands from a user of test unit 61. In a second embodiment, control module 90 is further structurally configured to receive logical commands via interface 80 from another test unit 61 connected to the opposing end of disturber cable 31. In a third embodiment, control is further structurally configured to receive both manual commands and logical commands.

In an alternative embodiment of test unit 61, transceiver module 100 can be structurally configured to selectively transmit an alien cross-talk test signal via interface 80 to another test unit 61 connected to the opposing end of disturber cable 31 or to be set in an idle state. For this alternative embodiment, transceiver module 100 is selectively set by control module 90 as either an active alien cross-talk test signal transmitter or an idle alien cross-talk test signal transmitter.

In an alternative embodiment of test unit 61, transceiver module 100 can be structurally configured to selectively terminate an alien cross-talk test signal received via interface 80 from another test unit 61 connected to the opposing end of disturber cable 31 or to be set in an idle state. For this alternative embodiment, transceiver module 100 is selectively set by control module 90 as either an active alien cross-talk test signal terminator or an idle alien cross-talk test signal terminator.

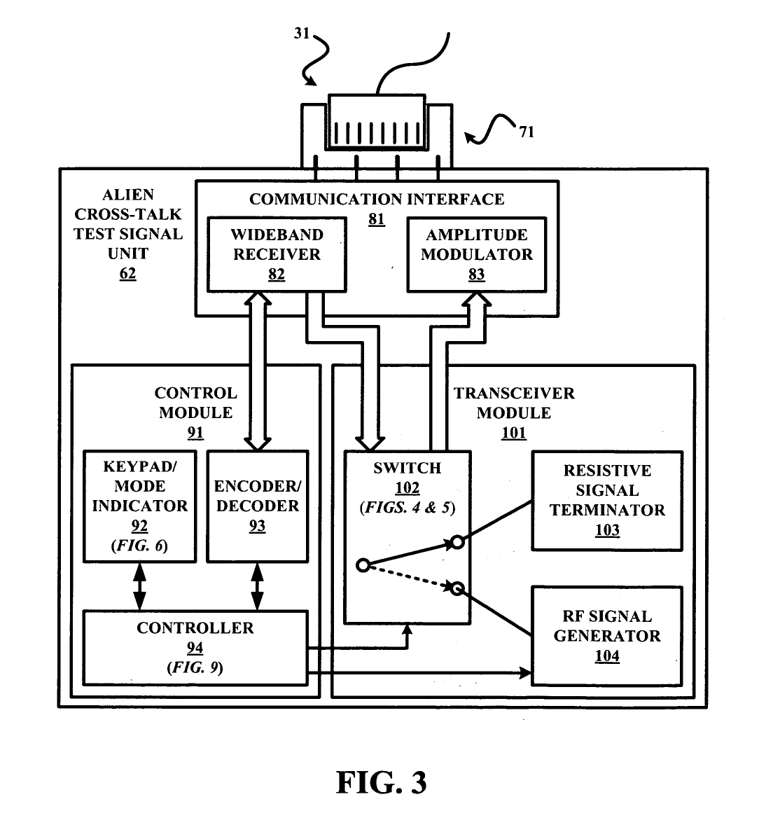

FIG. 3 illustrates a specific embodiment 62 of alien cross-talk test signal unit 60 (FIG. 1). Cross-talk test unit 62 employs cable jack 71, a communication interface 81, a control module 91 and a transceiver module 101. Cable jack 71 is structurally configured to connect test unit 62 to one end of a disturber cable 31 having four (4) wire pairs (i.e., M=4) as shown.

Communication interface 81 includes a wideband receiver 82 structurally configured to exchange commands with and receive alien cross-talk test signals in the form of RF test signals from another test unit 62 connected to an opposing end of disturber cable 31 (not shown). Communication interface 81 further includes an amplitude modulator 83 structurally configured to amplitude modulate and transmit alien cross-talk test signals in the form of RF test signal to another test unit 62 connected to an opposing end of disturber cable 31.

Transceiver module 101 includes a switch 102, a resistive signal terminator 103 and a RF signal generator 104. Switch 102 is structurally configured to switch between resistive signal terminator 103 and RF signal generator 104 as commanded by a controller 94 of control module 91.

Resistive signal terminator 103 is structurally configured to terminate RF test signals received via receiver 82 from another test unit 62 connected to the opposing end of disturber cable 31 when resistive signal terminal 103 is connected to wideband receiver 82 via switch 102. In an exemplary embodiment, resistive signal terminator 103 is structurally configured by design to provide a 100Ω differential termination and a 50Ω common mode termination.

RF signal generator 104 is structurally configured to generate the RF test signal having a definitive test pattern as commanded by controller 94 (e.g., linear, logarithmic, stepped-up and stepped-down) whereby the RF test signal is transmitted via modulator 83 to another test unit 62 connected to the opposing end of disturber cable 31 when RF signal generator 104 is connected to amplitude modulator 83 via switch 102. In an exemplary embodiment, RF signal generator 104 is structurally configured by design to generate an AC signal (e.g., sine waves, square waves, triangular waves, ramp waves and the like) whereby the RF test signal is test patterned as commanded by controller 94 as a frequency sweep test signal having a fixed stepped-up pattern at frequencies in an alien cross-talk measurement range (e.g., 1 MHZ to 1 GHz). Those having ordinary skill in the art will appreciate other types of test patterns for a frequency sweep test signal that are applicable to the present invention.

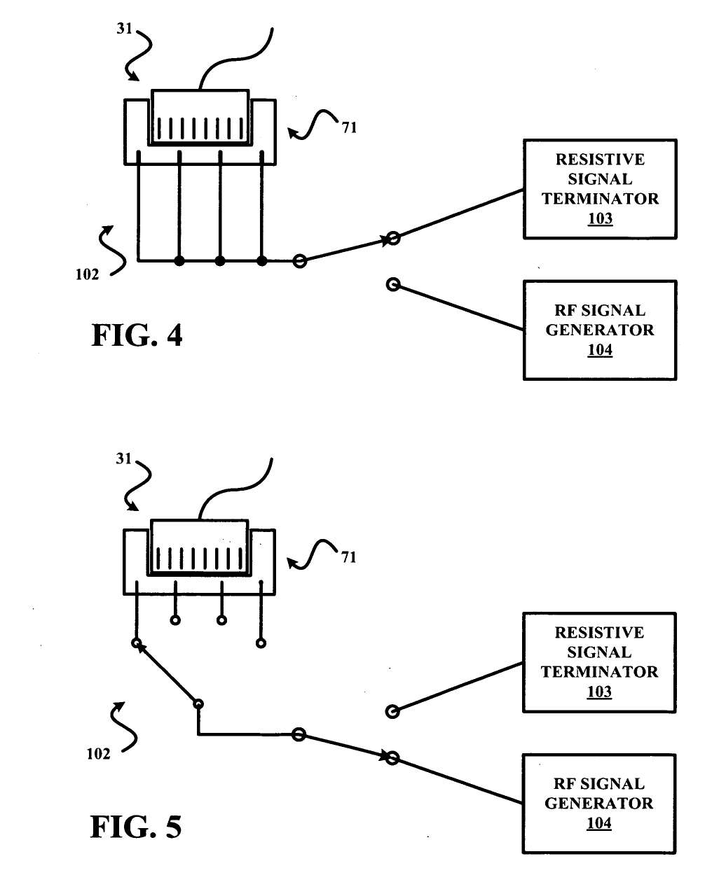

FIGS. 4 and 5 illustrates an exemplary structural configuration of switch 102 in the context of disturber cable 31 having the four (4) pairs of wires. Referring to FIG. 4, switch 102 is structurally configured to connect resistive signal terminator 103 via receiver 82 (not shown) to all four (4) pairs of wires of disturber cable 31 when commanded by controller 94 to connect resistive signal terminator 103 to disturber cable 31. Referring to FIG. 5, switch 102 is structurally configured to connect RF signal generator 104 to a specific pair of the (4) pairs of wires of disturber cable 31 via modulator 83 (not shown) when commanded by controller 94 to connect RF signal generator 104 to the specific pair of the (4) pairs of wires of disturber cable 31. In the context of the RF test signal being a stepped-up RF frequency sweep test signal, controller 94 can command switch 102 to individually select each wire pair during each frequency of the stepped-up RF frequency sweep test signal.

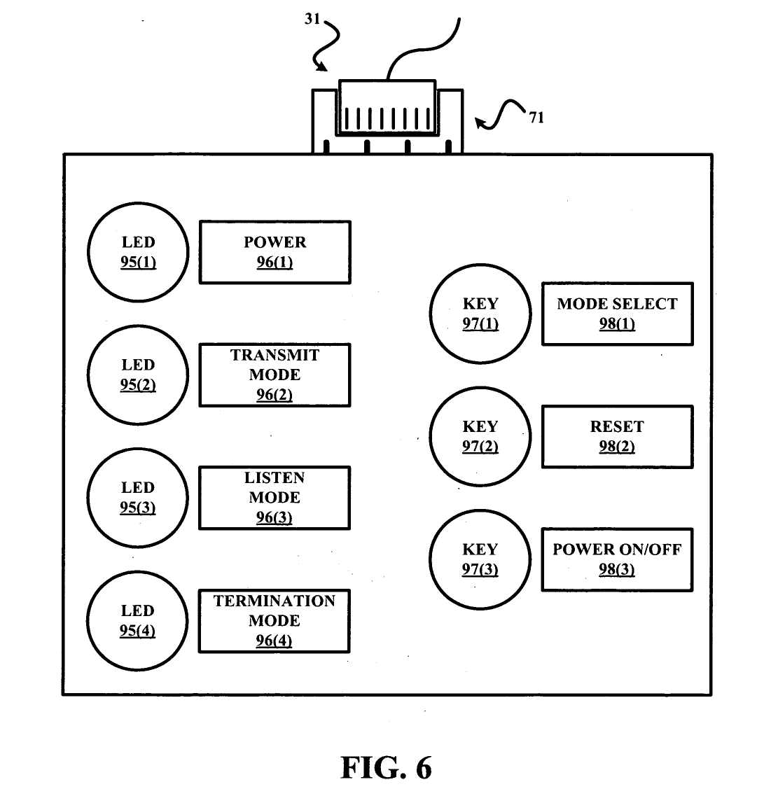

Referring again to FIG. 3, control module 91 includes a keypad/mode indicator 92, an encoder/decoder 93, and controller 94. Keypad/LED indicator 92 is structurally configured to visually indicate a working mode of test unit 62 as well as provide keys to facilitate a manual entry of commands to controller 94. FIG. 6 illustrates an exemplary embodiment of keypad/LED indicator 92 as mounted on an exterior of test unit 62.

Referring to FIGS. 3 and 6, indicator 92 includes four (4) pairs of a light emitting diode (“LED”) 95 and a working mode label 96, and three (3) pairs of a key 97 and a command label 98. An activation of LED 95(1) indicates test unit 62 is powered on. An activation of LED 95(2)indicates test unit 62 is set in a transmit mode defined by a connection of RF signal generator 104 to amplitude modulator 83 via switch 102 as commanded by controller 94 whereby test unit 62 is operating as a RF signal transmitter. An activation of LED 95(3) indicates test unit 62 is set in a listen mode defined by a connection of resistive signal terminator to wideband receiver 82 via switch 102 as commanded by controller 94 whereby test unit 62 is operating as an active RF signal terminator. An activation of LED 95(3) indicates test unit 62 is reset in a termination mode defined by a connection of resistive signal terminator to wideband receiver 82 via switch 102 as commanded by controller 94 whereby test unit 62 is operating as a default RF signal terminator.

Key 97(1) enables a user of test unit 62 to manually select one of working modes of test unit 62 among the transmit mode, the listen mode and the termination mode whereby a mode selection is indicated by one of the LED(s) 95(2), 95(3) and 95(4). Key 97(2) enables a user of test unit 62 to reset test unit 62 as well as another test unit 62 connected to an opposing end of disturber cable 31 whereby the reset in indicated by an activation of LED 95(4). Key 97(3) enables a user of test unit 62 to power on or off test unit 62 as indicated by an activation or deactivation of LED 95(1).

Referring again to FIG. 3, encoder/decoder 93 is structurally configured to encode commands generated by controller 94 for another test unit 62 connected to an opposing end of disturber cable 31 and to decode commands received on behalf of controller 94 from another test unit 62 connected to an opposing end of disturber cable 31. In one embodiment, the commands are in the form of RF logical signals that are encoded and decoded as needed in accordance with the following TABLE 1:

TABLE 1

| LOGICAL | | | | |
|---|---|---|---|---|
| SIGNAL | 01 | 10 | 11 | 00 |
| ACTION | Reset | Switch Working Mode | Feedback/Verification | Idle |

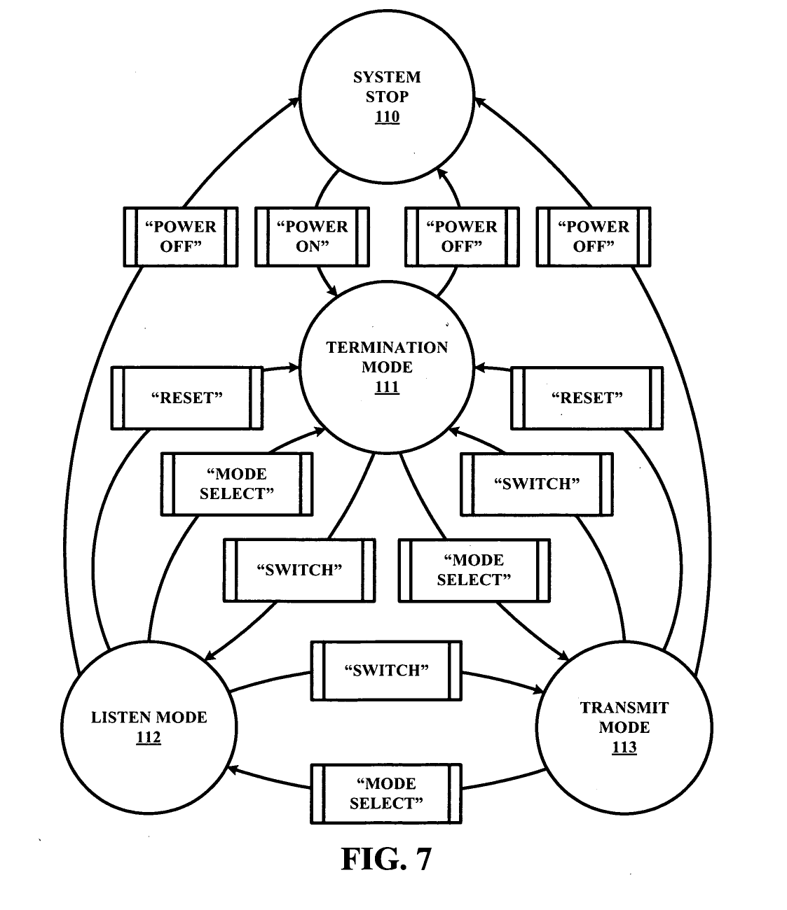

Controller 94 is structurally configured to control a test pattern of the RF test signal by RF signal generator 104, to set switch 102 as commanded (manually or logically) to thereby control a transmission of the RF test signal to another test unit 62 connected to the opposing end of disturber cable 31 or terminate a RF test signal received from another test unit connected to the opposing end of disturber cable 31, and to exchange logic commands in accordance with TABLE 1 with another test unit 62 connected to an opposing end of disturber cable 31. These logical functions enable controller 94 to control the working mode of test unit 62 when test unit is serving as a remote test unit. FIG. 7 illustrates a state diagram of test unit 62 to facilitate an understanding of the working mode control exhibited by controller 94.

Referring to FIGS. 6 and 7, a system stop 110 is an initial state of test unit 62. Controller 94 transitions test unit 62 to a termination mode 81 as represented by the “POWER ON” arrow in response to a powering on of generator 60 via power on/off key 97(3) as indicated by LED 95(1). In a manual context, a user of test unit 62 can use mode select key 97(1) to sequentially transition among transmit mode 113, listen mode 112 and termination mode 111 as represented by the “MODE SELECT” arrows. In a logical context, test unit 62 can automatically sequentially transition among termination mode 111, listen mode 112 and transmit mode 113 as represented by the “SWITCH” arrows in response to logical commands 10 received from another test unit 62 connected to an opposing end of disturber cable 31. Additionally, test unit 62 can immediately transition from either listen mode 112 and transmit mode 113 to termination mode 111 as represented by the “RESET” arrows in response to a manual command via reset key 97(2) (FIG. 6) or in response to a logical command 01 received from another test unit 62 connected to an opposing end of disturber cable 31. At any time, test unit 62 can be transitioned back to system stop 110 upon a powering off of test unit 62 via power on/off key 97(3) as represented by the “POWER OFF” arrows.

In accordance with the state diagram, a corresponding working mode of a near end test and a far end test involving test unit 62 is listed in the following TABLE 2:

TABLE 2

| | TESTNG CASES | | |
|---|---|---|---|
| | STANDY | ANEXT | AFEXT |
| NEAR END WORKING MODE: | Termination | Transmit | Listen |
| FAR END WORKING MODE: | Termination | Listen | Transmit |

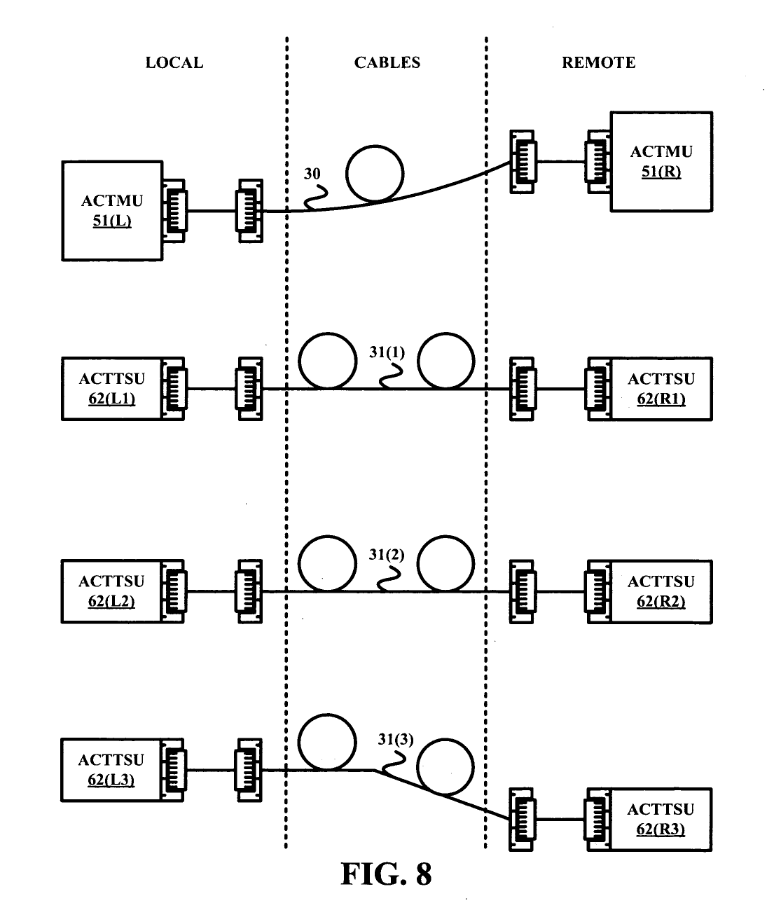

A description of an exemplary alien cross-talk environment will now be provided herein to facilitate an understanding of an alien cross-talking test in accordance with the present invention. In the exemplary alien cross-talk environment as shown in FIG. 8, the M number of wires pairs for the cables is four (4) and the N number of disturber cables is three (3).

Referring to FIG. 8, a local alien cross-talk measurement unit (“ACTMU”) 51(L) is connected to one end of victim cable 30 and a remote alien cross-talk measurement unit 51(R) is connected to an opposing end of victim cable 30. In one embodiment, alien cross-talk measurement units 51 are spectrum analyzers (e.g., a WireScope and a DualRemote, respectively, as sold by Agilent) or field cable testers having RJ-45 jacks or equivalent and memories that are programmed with computer code to selectively implement an alien cross-talk termination method in accordance with a flowchart 140 illustrated FIG. 11 and an alien cross-talk measurement method in accordance with a flowchart 150 illustrated in FIG. 12 as will be further explained herein.

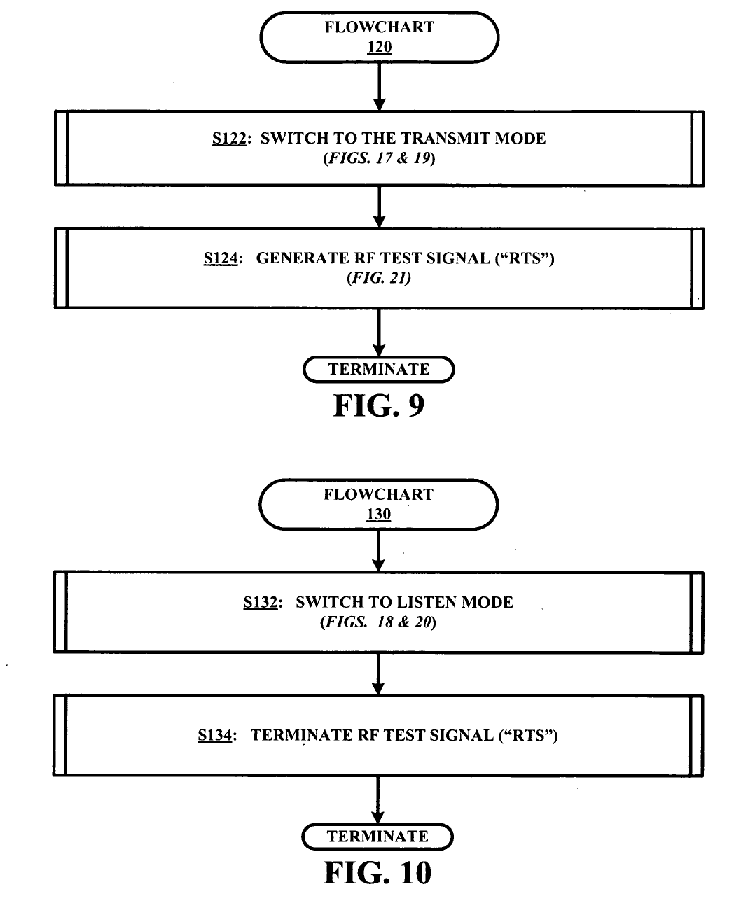

The three (3) alien cross-talk test signal unit (“ACTTSU”) 62 pairings each involve a local alien cross-talk test signal unit 62(L) connected to one end of a disturber cable 31 and a remote alien cross-talk test signal unit 62(R) connected to an opposing end of disturber cable 31. A controller 94 of each test unit 62 is programmed to selectively implement a RF test signal generation method in accordance with a flowchart 120 illustrated FIG. 9 and RF test signal termination method in accordance with a flowchart 130 illustrated in FIG. 10 as will be further explained herein.

Flowcharts 120 and 130 will now be explained in the context of each test unit 62 being in the termination mode prior to receiving a command to transition to either the transmit mode or the listen mode.

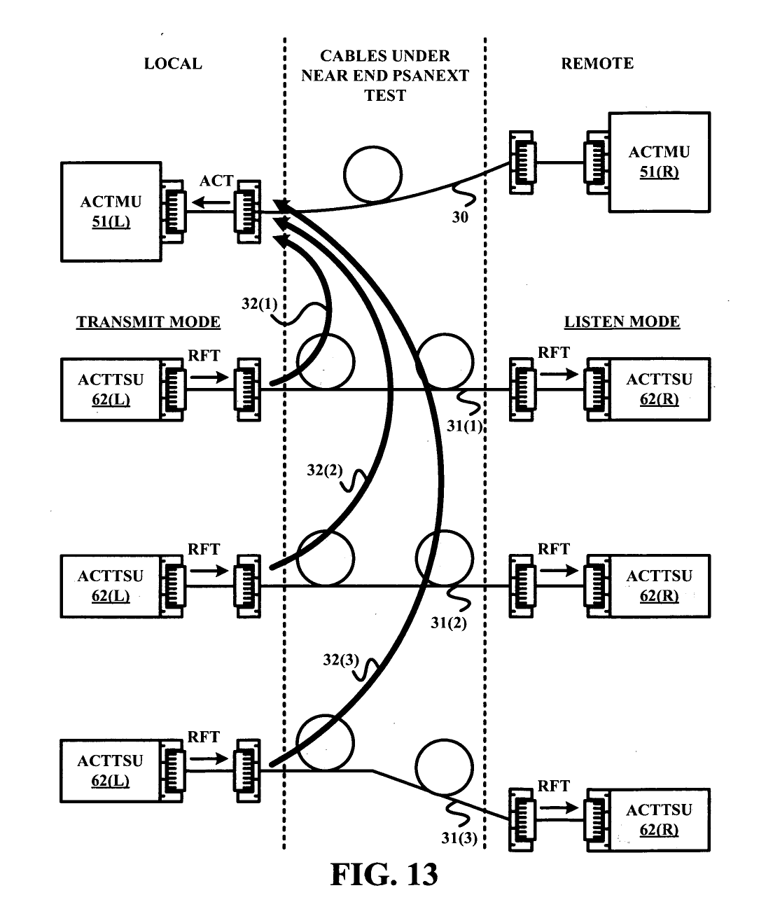

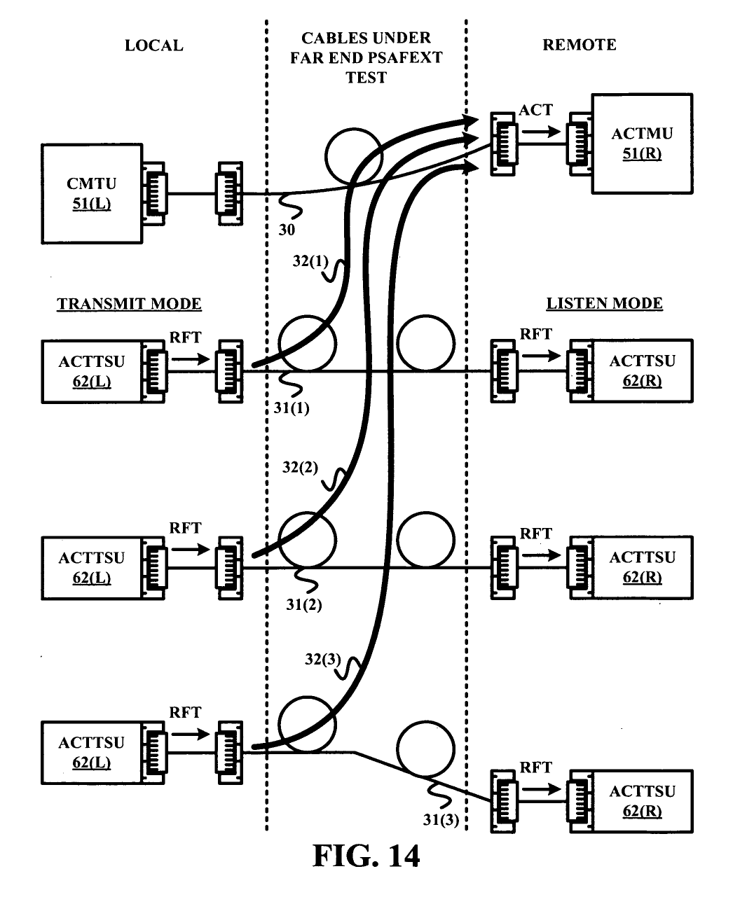

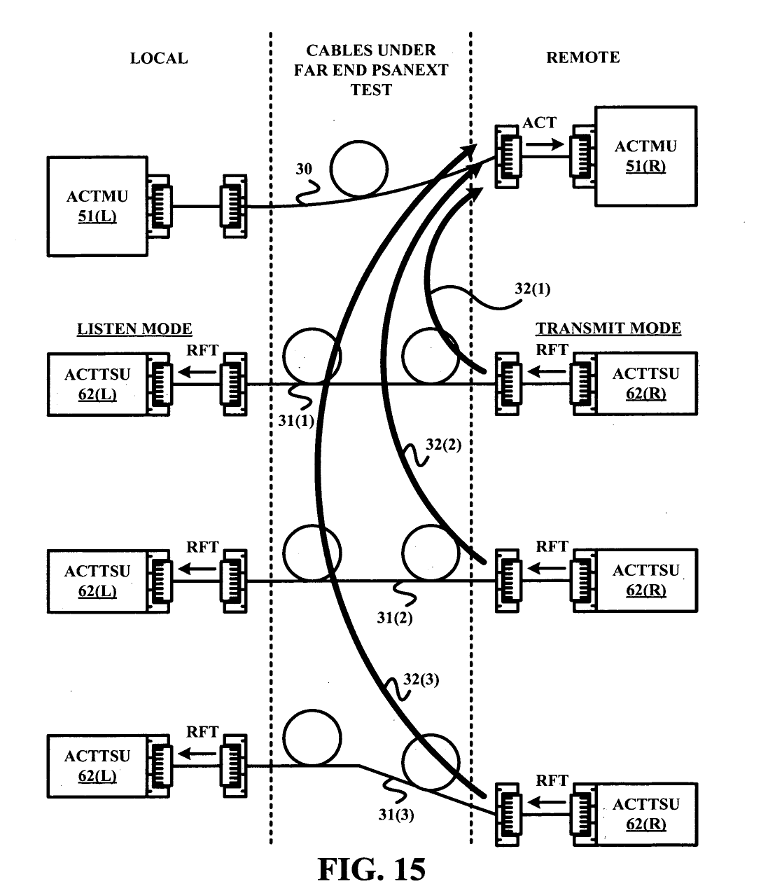

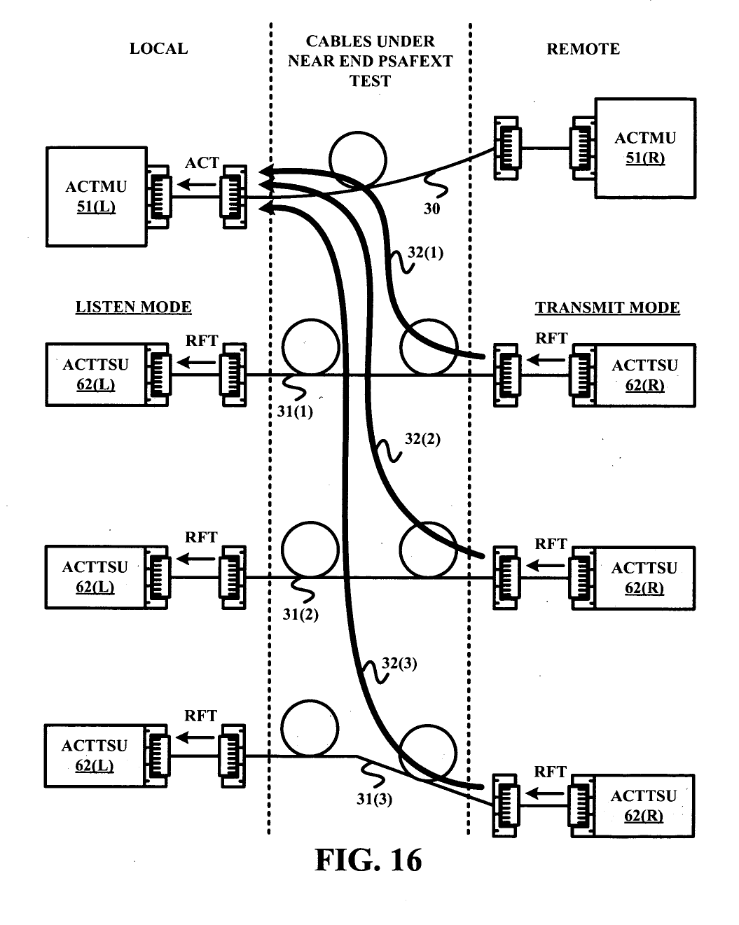

Referring to FIG. 9, controller 94 of a test unit 62 implements flowchart 120 in response to the test unit 62 serving as a local test unit under a near end powersum alien cross-talk near end (“PSANEXT”) cable test shown in FIG. 13 or a far end powersum alien cross-talk far end (“PSAFEXT”) cable test shown in FIG. 14, or as a remote test unit under a far end PSANEXT cable test shown in FIG. 15 or a near end PSAFEXT cable test shown in FIG. 16. A stage S122 of flowchart 120 encompasses controller 94 switching a corresponding test unit 62 from the termination mode to the transmit mode, and a stage S124 of flowchart 120 encompasses controller 94 commanding RF signal generator 104 to generate the RF test signal (“RFT”) whereby the RF test signal is transmitted by test unit 62 to the connected disturber cable 31 as shown in FIGS. 13-16.

Referring to FIG. 10, controller 94 of a test unit 62 implements flowchart 130 in response to the test unit 62 serving as a remote test unit under a near end PSANEXT cable test shown in FIG. 13 or a far end PSAFEXT cable test shown in FIG. 14, or as a local test unit under a far end PSANEXT cable test shown in FIG. 15 or a near end PSAFEXT cable test shown in FIG. 16. A stage S132 of flowchart 130 encompasses controller 94 switching a corresponding test unit 62 from the termination mode to the listen mode, and a stage S134 of flowchart 130 encompasses resistive signal terminator 103 terminating the RF test signal transmitted over the connected disturber cable 31 as shown in FIGS. 13-16.

Referring to FIG. 11, a controller (not shown) of measurement unit 51 implements flowchart 140 in response to the measurement unit 51 serving as a remote measurement unit under a near end PSANEXT cable test shown in FIG. 13 or a near end PSAFEXT cable test shown in FIG. 16, or as a local measurement unit under a far end PSAFEXT cable test shown in FIG. 14 or a far end PSANEXT cable test shown in FIG. 15. A stage S142 of flowchart 140 encompasses the controller of the measurement unit 51 being switched from an idle state to a termination mode, and a stage S144 of flowchart 140 encompasses a measurement unit 51 terminating an alien cross-talk signal (“ACT”) generated on victim cable 30 in response to alien cross-talk couplings 32 between victim cable 30 and disturber cables 31 as the RF test signals are being transmitted over the disturber cables 31 as shown in FIGS. 13-16.

Referring to FIG. 12, the controller of a measurement unit 51 implements flowchart 150 in response to the measurement unit 51 serving as a local measurement unit under a near end PSANEXT cable test shown in FIG. 13 or a near end PSAFEXT cable test shown in FIG. 16, or as a remote measurement unit under a far end PSAFEXT cable test shown in FIG. 14 or a far end PSANEXT cable test shown in FIG. 15. A stage S152 of flowchart 150 encompasses the controller of the measurement unit 51 being switched from an idle state to a measurement mode, and a stage S154 of flowchart 150 encompasses the measurement unit 51 measuring the alien cross-talk signal generated on victim cable 30 in response to alien cross-talk couplings 32 between victim cable 30 and disturber cables 31 as the RF test signals are being transmitted over the disturber cables 31 as shown in FIGS. 13-16. A final stage S165 of flowchart 150 encompasses the controller of the measurement unit 61 determining the alien cross-talk on victim cable 31 based on the measured alien cross-talk signal.

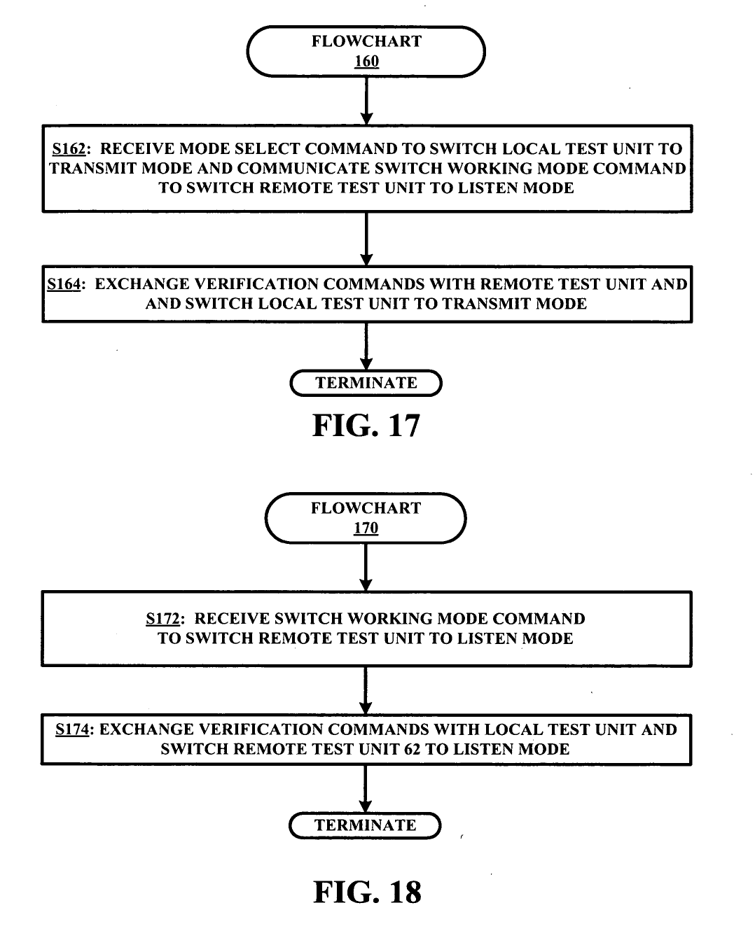

Exemplary embodiments of flowcharts 120-150 will now be described herein in connection with FIGS. 17-26 in the context of each test unit 62 shown in FIGS. 13-16 being set in the termination mode prior to receiving a command to transition to either the transmit mode or the listen mode.

FIG. 17 illustrates a flowchart 160 representative of a manual transmit mode selection method of the present invention applicable to test units 62 serving as local test units under near end PSANEXT shown in FIG. 13 and far end PSAFEXT shown in FIG. 14. A stage S162 of flowchart 160 encompasses a controller 94 of the local test unit 62(L) receiving a mode select command via a single press of key 97(1) (FIG. 6) to switch the local test unit 62(L) from the termination mode to the transmit mode and communicating two (2) switch working mode commands “10” to a corresponding remote test unit 62(R) to switch from the termination mode to the transmit mode and then to the listen mode. A stage S164 of flowchart 160 encompasses controller 94 of the local test unit 62(L) exchanging verification commands “11” with the remote test unit 62(R) and switching the local test unit 62(L) to the transition mode.

FIG. 18 illustrates a flowchart 170 representative of an automatic listen mode selection method of the present invention applicable to test units 62 serving as remote test units under near end PSANEXT shown in FIG. 13 and far end PSAFEXT shown in FIG. 14. A stage S172 of flowchart 170 encompasses a controller 94 of the remote test unit 62(R) receiving the two (2) switch working mode commands “10” from the local test unit 62(L) to switch the remote test unit 62(R) from the termination mode to the transmit mode and then to the listen mode. A stage S174 of flowchart 170 encompasses controller 94 of the remote test unit 62(R) exchanging verification commands “11” with the local test unit 62(L) and switching the remote test unit 62(R) from the termination mode to the transmit mode and then to the listen mode.

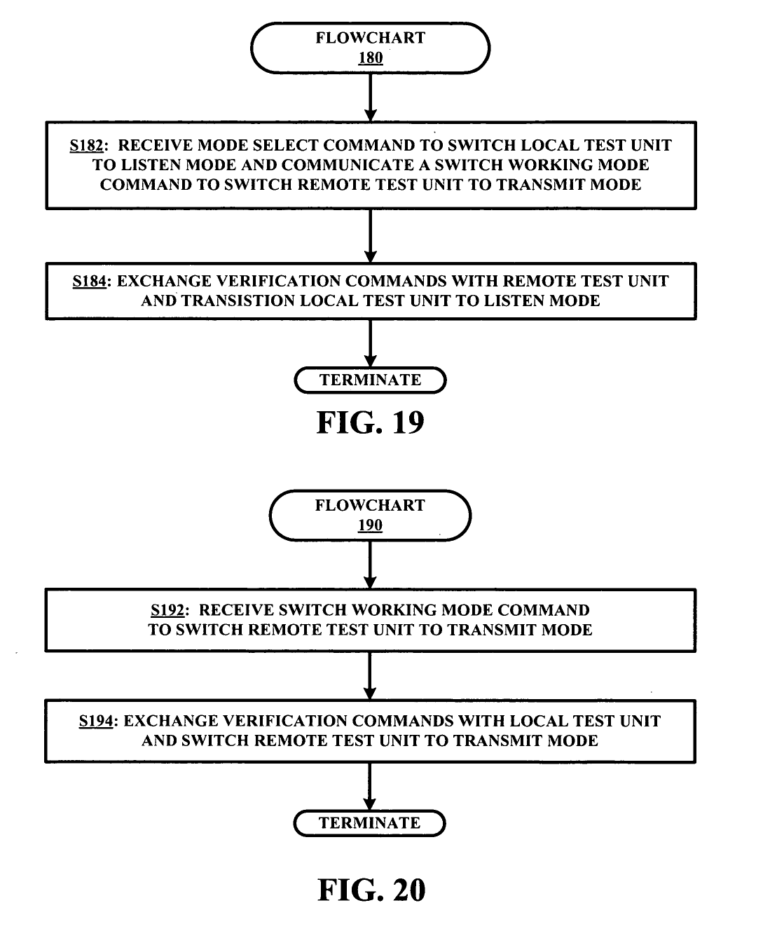

FIG. 19 illustrates a flowchart 180 representative of a manual listen mode selection method of the present invention applicable to test units 62 serving as local test units under far end PSANEXT shown in FIG. 15 and near end PSAFEXT shown in FIG. 16. A stage S182 of flowchart 180 encompasses a controller 94 of the local test unit 62(L) receiving two (2) mode select commands via a double press of key 97(1) (FIG. 6) to switch the local test unit 62(L) from the termination mode to the transmit mode and then to the listen mode, and communicating a single switch working mode command “10” to a corresponding remote test unit 62(R) to switch from the termination mode to the transmit mode. A stage S184 of flowchart 180 encompasses controller 94 of the local test unit 62(L) exchanging verification commands “11” with the remote test unit 62(R) and switching the local test unit 62(L) to the listen mode.

FIG. 20 illustrates a flowchart 190 representative of an automatic transmit mode selection method of the present invention applicable to test units 62 serving as remote test units under far end PSANEXT shown in FIG. 15 and near end PSAFEXT shown in FIG. 16. A stage S192 of flowchart 190 encompasses a controller 94 of the remote test unit 62(R) receiving the switch working mode command “10” from the local test unit 62(L) to switch the remote test unit 62(R) from the termination mode to the transmit mode. A stage S194 of flowchart 190 encompasses controller 94 of the remote test unit 62(R) exchanging verification commands “11” with the local test unit 62(L) and switching the remote test unit 62(R) from the termination mode to the transmit mode.

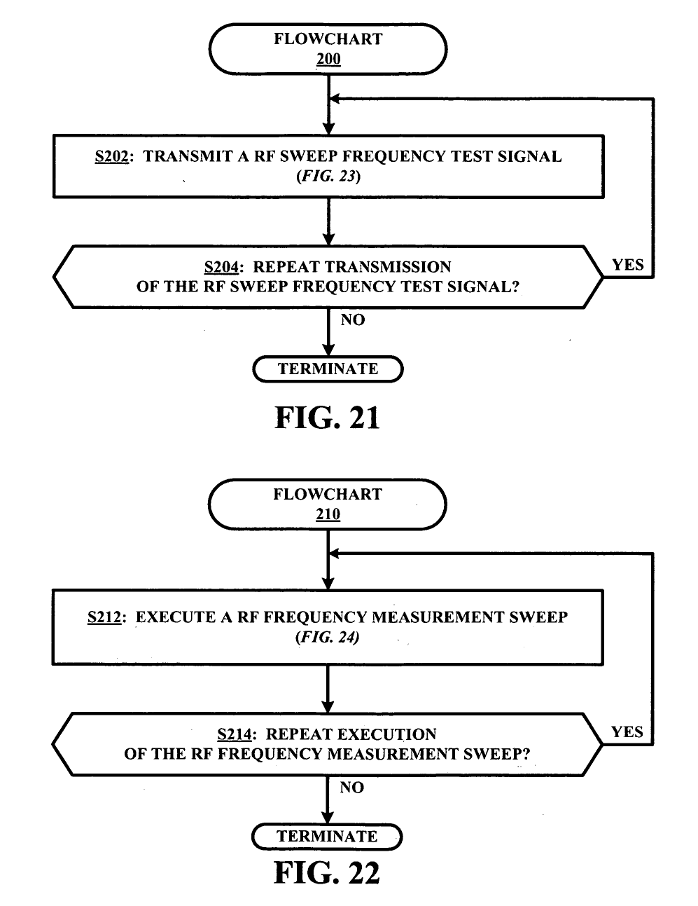

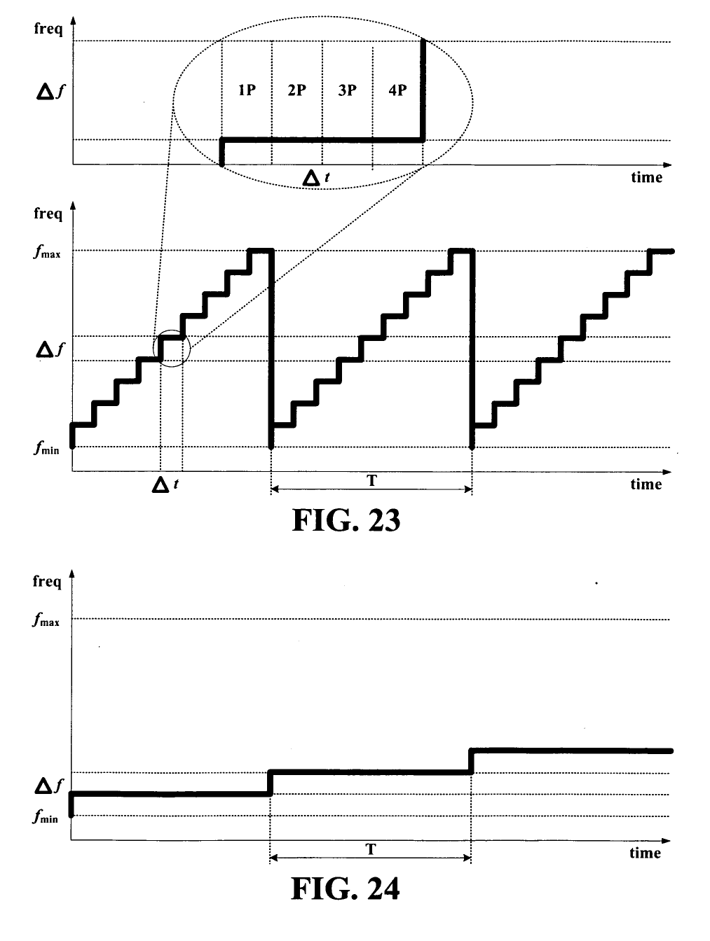

FIG. 21 illustrates a flowchart 200 representative of a RF frequency sweep test signal transmission method of the present invention as implemented by each test unit 62 shown in FIGS. 13-16 that are switched to the transmit mode. A stage S202 encompasses a controller 94 of a transmit mode test unit 62 controlling a transmission of a RF frequency sweep test signal on the connected disturber cable 31. An exemplary RF frequency sweep test signal as shown in FIG. 23 has a frequency sweep range of ƒ_{MIN} (e.g., 1 MHz) to ƒ_{MAX} (e.g., 1 GHz) over a time period T whereby the frequency of the signal is incrementally increased by a frequency step size Δƒ over each time period Δt. Furthermore, for a four (4) pair wire, the signal is transmitted to a different wire pair for ¼Δt for each frequency step size Δƒ as shown in FIG. 23.

Referring again to FIG. 21, a stage S204 of flowchart 200 encompasses a controller 94 of the transmit mode test unit 62 determining whether to repeat the transmission of the RF frequency sweep test signal on the disturber cable 31 or to terminate flowchart 200. In one embodiment, a determination policy is implemented during stage S204 with the determination policy being based on a recognition that all of the test units 62 set in the transmit mode may or may not be synchronized with measurement units 50 whereby it may be necessary to repeat the transmission for a specific amount of time to ensure proper measurement of the alien cross-talk on victim cable 30.

FIG. 22 illustrates a flowchart 210 representative of a RF frequency sweep measurement method of the present invention as implemented by each measurement unit 51 shown in FIGS. 13-16 that are switched to the measurement mode. A stage S212 encompasses the measurement unit 51 executing a RF frequency measurement sweep of victim cable 30. An exemplary RF frequency measurement sweep, of which three (3) steps are shown in FIG. 24, has a frequency sweep range of ƒ_{MIN} (e.g., 1 MHz) to ƒ_{MAX} (e.g., 1 GHz) over a time period xT (x being the number of frequency steps) whereby the frequency of the measurement sweep is incrementally increased by a frequency step size Δƒ over each time period T.

Referring again to FIG. 22, a stage S214 of flowchart 200 encompasses a measuring unit 51 determining whether to repeat the RF frequency measurement sweep on the victim cable 30 or to terminate flowchart 220. In one embodiment, a determination policy is implemented during stage S214 with the determination policy being based on a recognition that all of the test units 62 set in the transmit mode may or may not be synchronized with the measurement unit 51 whereby it may be necessary to repeat the measurement sweep for a specific number of times.

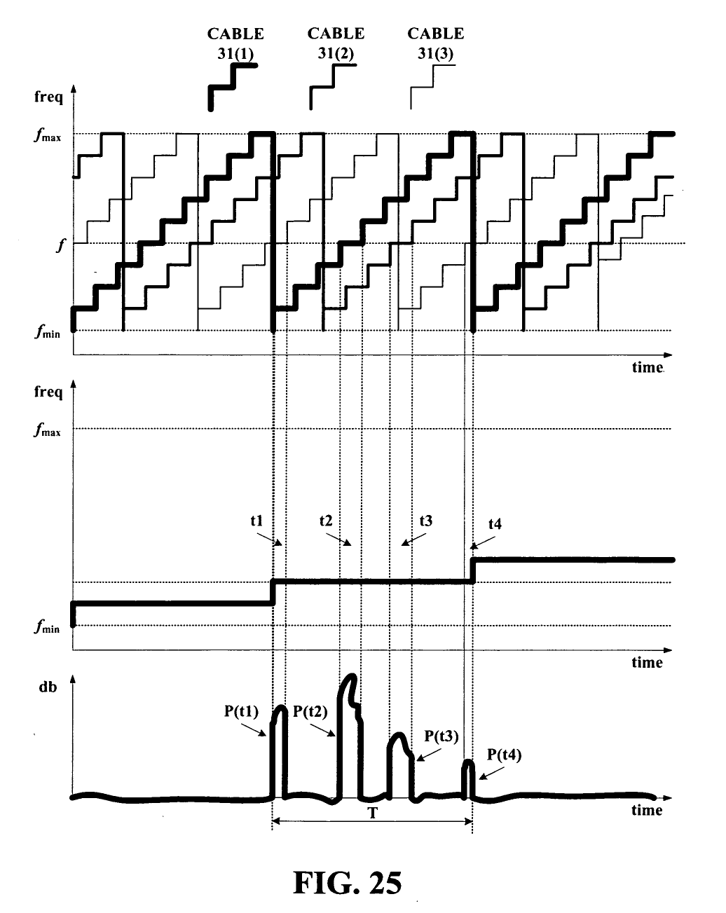

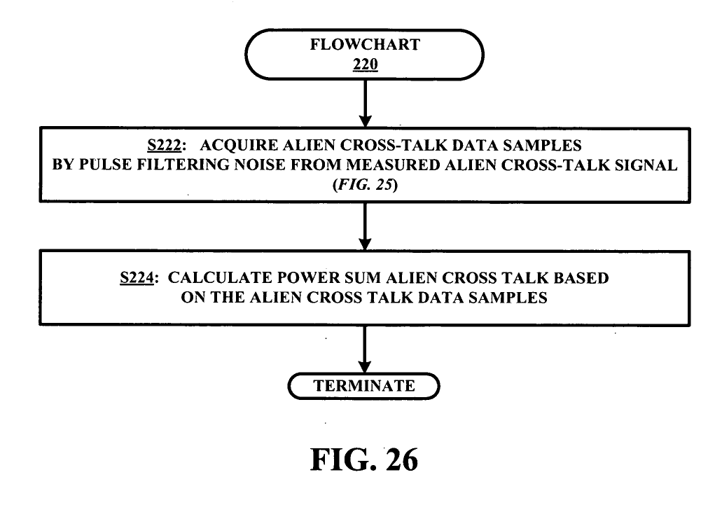

FIG. 25 illustrates an exemplary measurement of an alien cross-talk signal on victim cable in the context of RF frequency sweep test signals of FIG. 23 being simultaneously and asynchronously transmitted on disturber cables 31 and the RF frequency measurement sweep of FIG. 24 being performed on victim cable 30 for a particular frequency ƒ. As shown in FIG. 25 for one of the T periods of the RF frequency measurement sweep, exemplary alien cross-talk data samples P(t1), P(t2), P(t3) and P(t4) in the alien cross-talk signal on victim cable 30 occur during respective time periods t1, t2, t3 and t4. Specifically, alien cross-talk data sample P(t1) is generated in response to the RF frequency sweep test signal on disturber cable 31(3) and the RF frequency measurement sweep on victim cable 30 having frequency ƒ during time period t1 as shown in FIG. 25. Alien cross-talk data sample P(t2) is generated in response to the RF frequency sweep test signal on disturber cable 31(1) and the RF frequency measurement sweep on victim cable 30 having frequency ƒ during time period t2 as shown in FIG. 25. Alien cross-talk data sample P(t3) is generated in response to the RF frequency sweep test signal on disturber cable 31(2) and the RF frequency measurement sweep on victim cable 30 having frequency ƒ during time period t3 as shown in FIG. 25. Alien cross-talk data sample P(t4) is generated in response to the RF frequency sweep test signal on disturber cable 31(3) and the RF frequency measurement sweep on victim cable 30 having frequency ƒ during time period t4 as shown in FIG. 25. From this description of FIG. 25, those having ordinary skill in the art will appreciate the generation of four (4) alien cross-talk data samples for each frequency of the RF frequency measurement sweep of victim cable 30. Those having ordinary skill in the art will appreciate that each alien cross-talk data sample P can be equally divided into four (4) segments with each segment corresponding to a particular wire pair of victim cable 30. To this end, those having ordinary skill in the are will further appreciate that alien cross-talk data sample P(t1) and alien cross-talk data sample P(t4) both correspond to disturber cable 31(3) and therefore have to be combined as one data sample.

FIG. 26 illustrates a flowchart 220 representative of an alien cross-talk determination method of the present invention. A stage S222 of flowchart 220 encompasses a measurement unit 51 acquiring data samples from a measured alien cross-talk signal. These data samples will be first processed to filter measurement noise. This filtering, for example, can be in the form of a threshold filtering, allowing samples with value greater than a pre-defined threshold unchanged while setting the data samples with values below the threshold level to zero. In one embodiment, the threshold filtering is implemented in accordance with the following equation [1]:
Pk=Pk′if Pk′>Th
Pk=0 if Pk′<Th [1]

where Pk′ is kth data sample, Th is pre-determined threshold and Pk is the filtered data sample. For example, as shown in FIG. 25, a threshold filtering of the noise of the measured alien cross-talk signal involves the sampled pulses P(t1)-P(t4) of the alien cross-talk signal exceeding the threshold Th with the remaining noise of the alien cross-talk signal is set to zero. Those having ordinary skill in the art will appreciate the value of the pre-determined TH can be a function of a measured amount of noise on the victim cable absent any alien cross-talk coupling between the victim cable and any disturber cable.

A stage S224 of flowchart 220 encompasses a measurement unit 51 calculating a powersum alien cross-talk on victim cable 30 based on the filtered data samples in the stage 222. In one embodiment, the powersum alien cross-talk PSAXT on victim cable 30 is calculated in accordance with the following equation [2]:

$$PSAXT = \frac{M}{K} {\sum }_{k = 1}^{xK} {P}_{k} \qquad [ 2 ]$$

where M is the number of wire pairs in a cable (for example 4). Pkε[1,xK] are the filtered data samples per frequency at stage 222, x is the number of frequency steps, K is the total number of data samples acquired in the measurement unit in a duration Δt (corresponding to one frequency step of the test signal as in FIG. 23). The value of K is for example determined by the sampling speed of data acquisition hardware.

Duration of one frequency step in the measurement frequency sweep, T, is determined by T=x·Δt. In other words, one frequency step duration for measurement sweep equals entire sweep duration of test sweep.

From the above equation [2], those having ordinary skill in the art will appreciate that a summation of all of the samples of acquired data sample per frequency followed by a division of the total number of samples K per frequency step and a multiple of M provides a straightforward calculation of a powersum alien cross talk for a PSANEXT test or a PSAFEXT test.

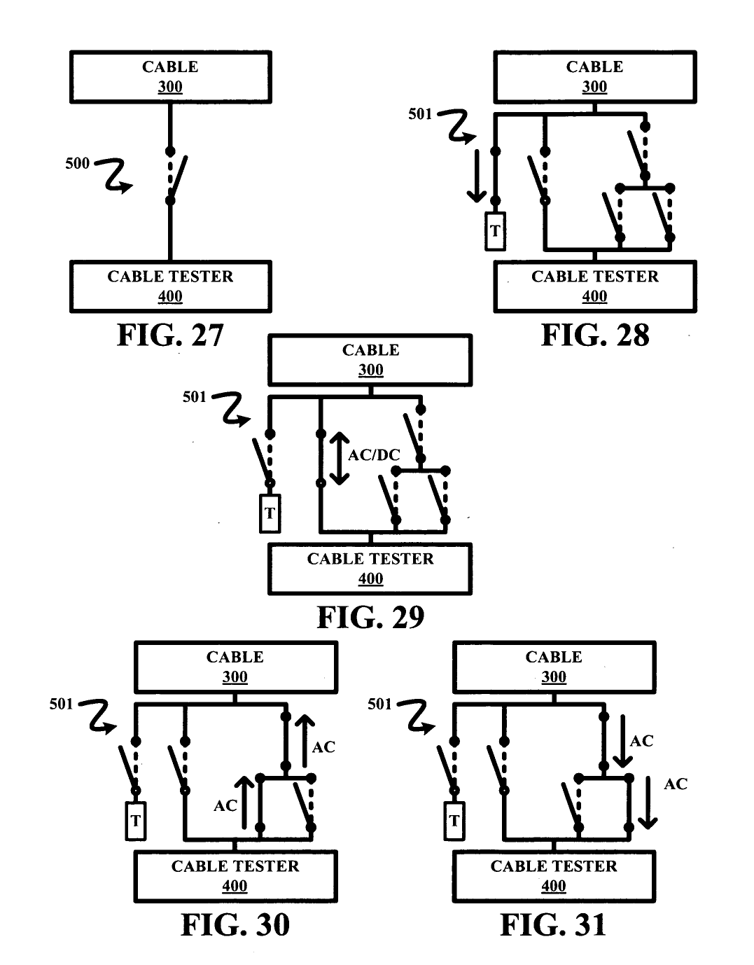

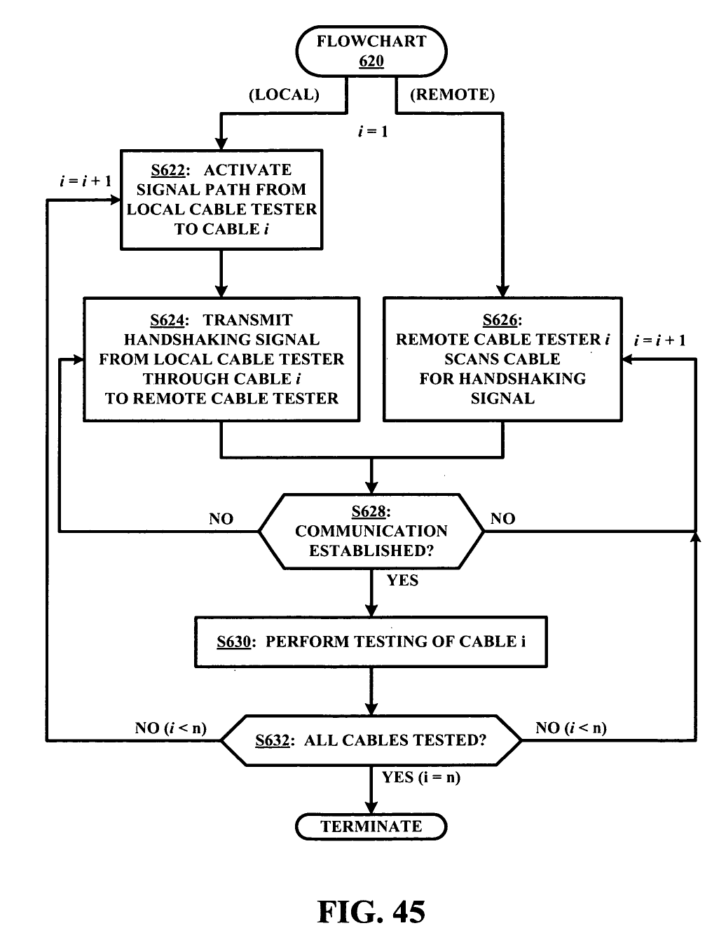

The following description of FIGS. 27-57 is directed to a cable testing system of the present invention created for purposes of selectively conducting either a multi-cable testing of a plurality of cables, or an alien cross-talking cable testing of a victim cable and one or more disturber cables. To this end, the cable testing system is generally premised on providing a signal path between a cable and a cable tester, and on a controlled switching of the signal path between an activated state and a deactivated state based on commands from the cable tester, such as, for example, a signal path 500 shown in FIG. 27 between a cable 300 and a cable tester 400 and a controlled switching of signal path 500 between an activated state (i.e., a closed signal path) and a deactivated state (i.e., an open signal path as shown) based on commands from cable tester 400.

For purposes of selectively conducting either a multi-cable testing of a plurality of cables or an alien cross-talking cable testing of a victim cable and one or more disturber cables, the cable testing system is specifically premised on providing a signal path between a cable and a cable tester and a controlled switching of the signal path between an activated state and a deactivated state based on commands from the cable tester with the activated state having a multi-cable testing mode and an alien cross-talking testing mode. For example, as shown in FIGS. 28-31, a signal path 501 is provided between cable 300 and cable tester 400. FIG. 28 illustrates a switching of signal path 501 to a deactivated state whereby any signal transmitted from cable 300 is terminated (e.g., by a 100Ω differential and 50Ω common mode termination) and cable tester 400 is incapable of attempting to transmit a signal to cable 300. FIG. 29 illustrates a switching of signal path 501 to a multi-cable testing mode of an activated state whereby cable 300 and cable tester 400 are capable of transmitting AC/DC signals to each other. FIG. 30 illustrates a switching of signal path 501 to a test signal transmission aspect of an alien cross-talking mode of an activated state whereby cable tester 400 is capable of transmitting a AC test signal to cable 300. FIG. 30 illustrates a switching of signal path 501 to a test signal reception aspect of an alien cross-talking mode of an activated state whereby cable tester 400 is capable of receiving an AC test signal from cable 300.

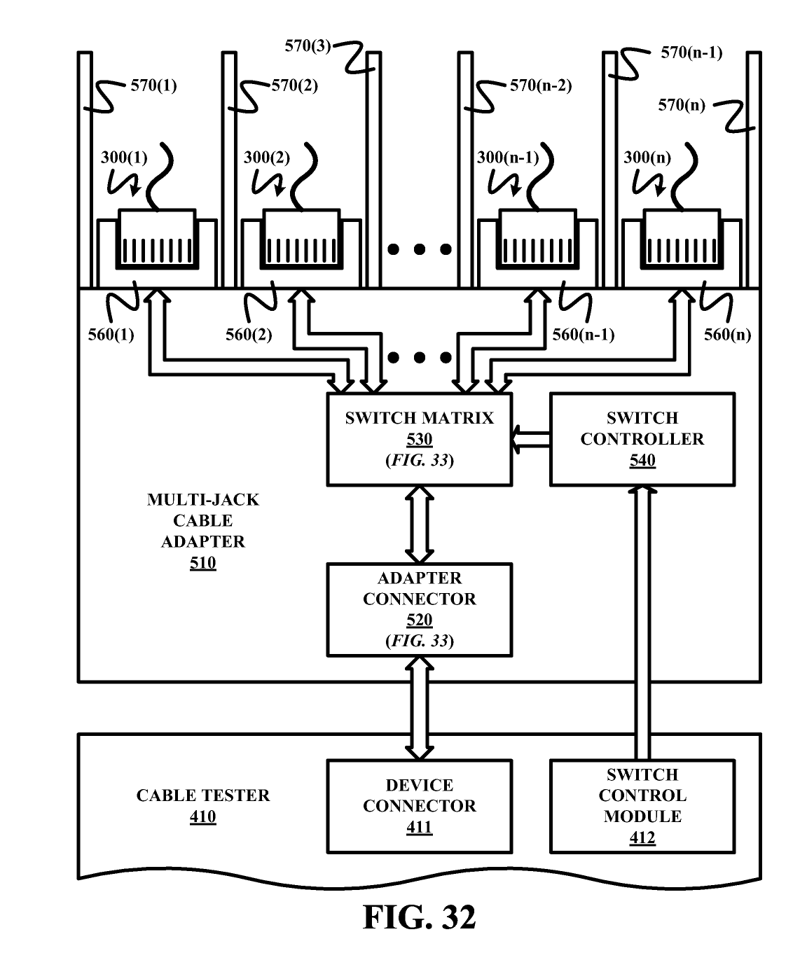

FIG. 32 illustrates one embodiment of a multi-jack cable adapter 510 for establishing a signal path between a cable tester 410 and each cable 300 of a n number of cables under the inventive principles shown in FIGS. 27-31. To his end, multi-jack cable adapter 510 employs an adapter connector 520 that is structurally configured to connect to a device connector 411 of cable tester 410 to thereby establish an electrical communication between multi-jack cable adapter 510 and cable tester 410. In one embodiment, this electrical communication between multi-jack cable adapter 510 and cable tester 410 is based on a M number of wire pairs of each cable 300 whereby a M number of test connection nodes are established by adapter connector 520 as will be further explained herein.

Multi-jack cable adapter 510 further employs a n number of jacks 560 (e.g., RJ-45 jacks) for connecting the n number of cables 300 to multi-jack adapter 510 to thereby establish electrical communication between multi-jack adapter 510 and each cable 300. In one embodiment, this electrical communication between multi-jack cable adapter 510 and each cable tester 300 is based on the M number of wire pairs of each cable 300 whereby a M number of cable connection nodes are established by jacks 560 as will be further explained herein.

Multi-jack cable adapter 510 further employs a switch matrix 530 that is structurally configured to provide the signal paths between cable tester 410 and cables 300, and a switch controller 540 that is structurally configured to selectively activate and deactivate each signal path as commanded by a switch control module 412 of cable tester 410. In one embodiment, switch matrix 540 provides the signal paths based on the M number of wire pairs of each cable 300 whereby each test connection node established by adapter connector 520 branches to a corresponding cable connection node of each cable jack 560 as will be further explained herein.

As related to multi-cable testing, switch control module 412 communicates a command to switch controller 540 directed to activating a signal path to a specific cable of the cables 300 (e.g., activated mode shown in FIG. 29) while deactivating the remaining signal paths to the other cables 300 (e.g., deactivated mode shown in FIG. 28). In response thereto, switch controller 540 communicates control signals to switch matrix 530 based on an interpretation of the command from switch control module 412 to thereby activate the signal path to the specific cable of the cables 300 while deactivating the remaining signal paths to the other cables 300.

As related to alien cross-talk testing, switch control module 412 communicates a command to switch controller 540 directed to activating one or more signal paths to a victim cable and/or one or more disturber of cables of cables 300 (e.g., activated mode/test signal transmission aspect shown in FIG. 30 and activated mode/test signal reception aspect shown in FIG. 3 1) while deactivating the remaining signal paths to the other cables 300 (e.g., deactivated mode shown in FIG. 28). In response thereto, switch controller 540 communicates control signals to switch matrix 530 based on an interpretation of the command from switch control module 412 to thereby activate the required alien cross-talk testing signal paths to the victim cable of the cables 300 and/or the one or more disturber cables of cables 300 while deactivating the remaining signal paths to the remaining cables 300.

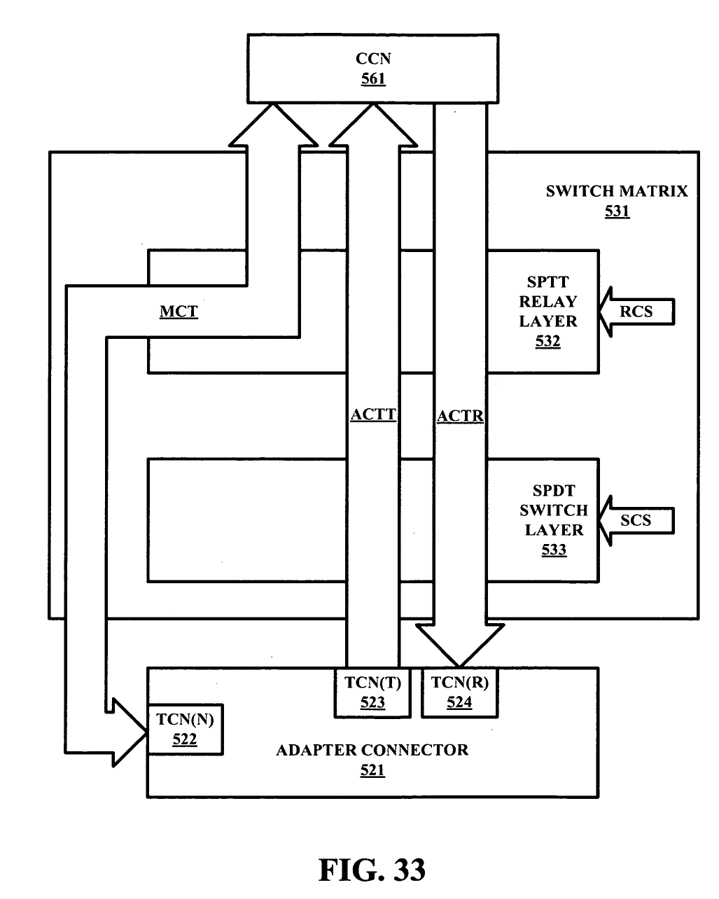

FIG. 33 illustrates one embodiment 521 of adapter connector 520 (FIG. 32) and one embodiment 531 of switch matrix 530 (FIG. 32). Switch matrix 531 employs a single pole triple throw (“SPTT”) relay layer 532 structurally configured to selectively activate and deactivate each multi-cable testing signal path (“MCT”) from a testing connection node (“TCN(N)”) 522 of adapter connector 521 as directed by a relay control signal RCS from switch controller 540 (FIG. 32). Switch matrix 531 employs a single pole double throw (“SPDT”) switch layer 533 structurally configured in conjunction with SPTT relay layer 532 to selectively activate and deactivate each alien cross-talk transmission signal path (“ACTT”) from a testing connection node (“TCN(T)”) 523 of adapter connector 521 as directed by a respective relay control signal RCS and a switching control signal SCS from switch controller 540 (FIG. 32). SPDT switch layer 533 is further structurally configured in conjunction with SPTT relay layer 532 to selectively activate and deactivate each alien cross-talk reception signal path (“ACTR”) from a testing connection node (“TCN(R)”) 524 of adapter connector 521 as directed by respective relay control signal RCS and switching control signal SCS from switch controller 540 (FIG. 32).

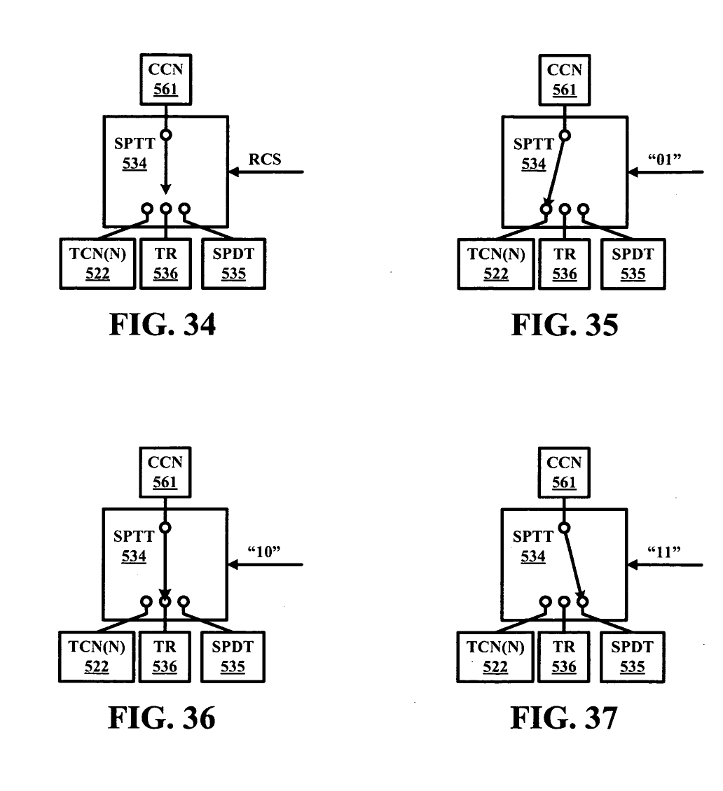

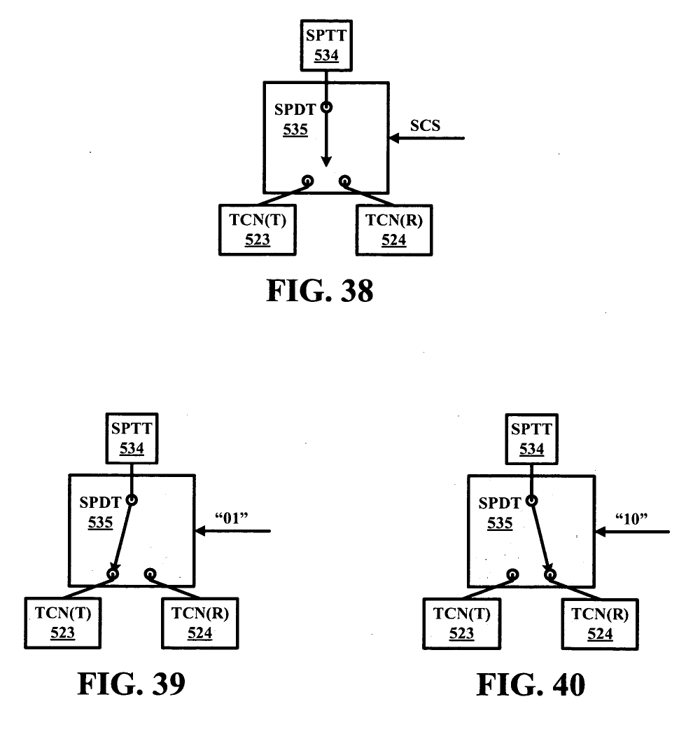

In one embodiment of SPTT relay layer 532 and of SPTDT switch layer 533, as shown in FIGS. 34 and 38, a singe pole triple throw switch (“SPTT”) 534 (FIG. 34) and a single pole double throw switch (“SPDT”) 535 (FIG. 38) are used to selectively connect testing connection node 522 to one of the cable connection nodes 561. In response to relay control signal RCS being “01”, SPTT 534 is switched to the multi-cable testing activated mode as shown in FIG. 35 whereby the associated cable connection node 561 and testing connection node 522 are in electrical communication for purposes of exchanging AC/DC test signals. In response to relay control signal RCS being “10”, SPTT 534 is switched to the deactivated mode as shown in FIG. 36 whereby the associated cable connection node 561 and a termination (“TR”) 536 are in electrical communication for purposes of terminating any signal directed from cable connection node 561 to SPTT 534.

In response to relay control signal RCS being “11” and switch control signal SCS being “10”, SPTT 534 is switched to the alien cross-talk testing activated mode as shown in FIG. 37 and SPDT switch 535 is switched to the testing signal reception aspect of the alien cross-talk testing activated mode as shown in FIG. 39 whereby the associated cable connection node 561 (FIG. 37) and a testing connection node 523 (FIG. 38) are in electrical communication for purposes of transmitting a AC test signal from cable connection node 561 to testing connection node 523. In response to relay control signal RCS being “11” and switch control signal SCS being “10”, SPTT 534 is switched to the alien cross-talk testing activated mode as shown in FIG. 37 and SPDT switch 535 is switched to the testing signal transmission aspect of the alien cross-talk testing activated mode as shown in FIG. 40 whereby the associated cable connection node 561 (FIG. 37) and a testing connection node 524 (FIG. 38) are in electrical communication for purposes of transmitting a AC test signal from testing connection node 524 to cable connection node 561.

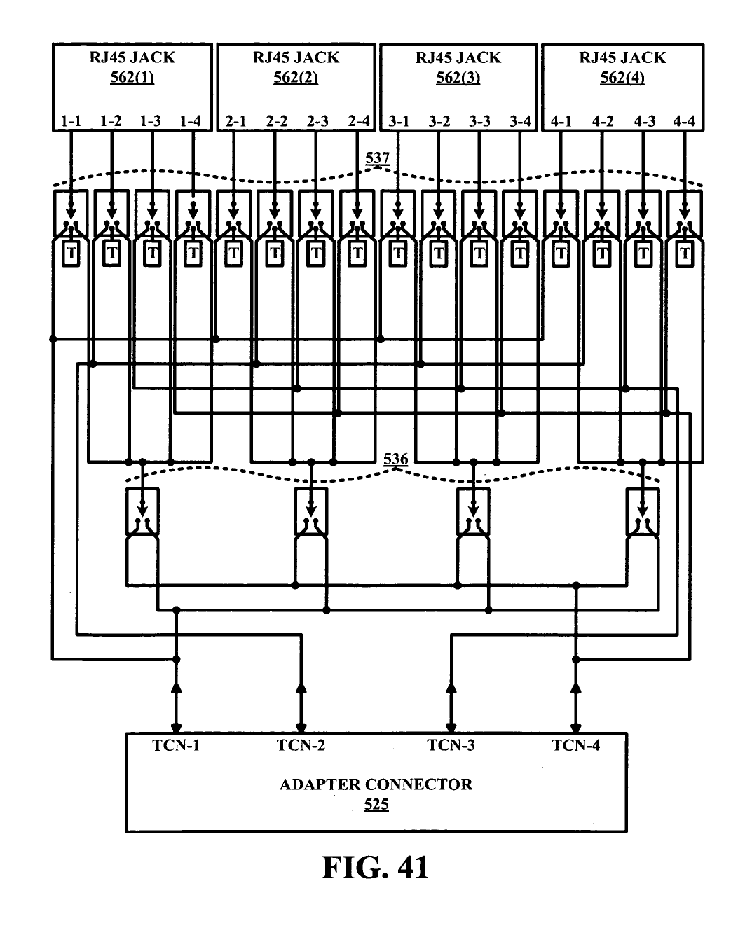

FIG. 41 illustrates a SPDT switch layer 536 employing four (4) SPDT 535 (FIGS. 38-40) and a SPTT relay layer 537 employing sixteen (16) SPTT 534 (FIGS. 34-37). This switch matrix embodiment is structurally configured with a network of signal paths for multi-cable testing and alien cross-talk cable testing.

A first set of multi-cable testing signal paths consists of a signal path from a testing connection node TCN-1 of an adapter connector 525 through layer 537 to a cable connection node 1-1 of a RJ45 jack 562(1), a signal path from testing connection node TCN-1 of adapter connector 525 through layer 537 to a cable connection node 2-1 of a RJ45 jack 562(2), a signal path from testing connection node TCN-1 of an adapter connector 525 through layer 537 to a cable connection node 3-1 of a RJ45 jack 562(3) and a signal path from testing connection node TCN-1 of adapter connector 525 through layer 537 to a cable connection node 4-1 of a RJ45 jack 562(4).

A second set of multi-cable testing signal paths consists of a signal path from a testing connection node TCN-2 of an adapter connector 525 through layer 537 to a cable connection node 1-2 of RJ45 jack 562(1), a signal path from testing connection node TCN-2 of adapter connector 525 through layer 537 to a cable connection node 2-2 of RJ45 jack 562(2), a signal path from testing connection node TCN-2 of an adapter connector 525 through layer 537 to a cable connection node 3-2 of RJ45 jack 562(3) and a signal path from testing connection node TCN-2 of adapter connector 525 through layer 537 to a cable connection node 4-2 of RJ45 jack 562(4).

A third set of multi-cable testing signal paths consists of a signal path from a testing connection node TCN-3 of an adapter connector 525 through layer 537 to a cable connection node 1-3 of RJ45 jack 562(1), a signal path from testing connection node TCN-3 of adapter connector 525 through layer 537 to a cable connection node 2-3 of RJ45 jack 562(2), a signal path from testing connection node TCN-3 of an adapter connector 525 through layer 537 to a cable connection node 3-3 of RJ45 jack 562(3) and a signal path from testing connection node TCN-3 of adapter connector 525 through layer 537 to a cable connection node 4-3 of RJ45 jack 562(4).

A fourth set of multi-cable testing signal paths consists of a signal path from a testing connection node TCN-4 of an adapter connector 525 through layer 537 to a cable connection node 1-4 of RJ45 jack 562(1), a signal path from testing connection node TCN-4 of adapter connector 525 through layer 537 to a cable connection node 2-4 of RJ45 jack 562(2), a signal path from testing connection node TCN-4 of an adapter connector 525 through layer 537 to a cable connection node 3-4 of RJ45 jack 562(3) and a signal path from testing connection node TCN-4 of adapter connector 525 through layer 537 to a cable connection node 4-4 of RJ45 jack 562(4).

For multi-cable testing, the relay control signals are solely used to selectively activate and deactivate each of the aforementioned signal paths. Specifically, the following TABLE 1 lists a relay control signal sequence to activate each signal path between adapter connector 525 and RJ45 jack 562(1) in accordance with FIG. 35 and to deactivate each signal path between adapter connector 525 and the remaining RJ45 jacks 562 in accordance with FIG. 36:

TABLE 1

| | 1-1 | 1-2 | 1-3 | 1-4 | 2-1 | 2-2 | 2-3 | 2-4 | 3-1 | 3-2 | 3-3 | 3-4 | 4-1 | 4-2 | 4-3 | 4-4 |
|---|---|---|---|---|---|---|---|---|---|---|---|---|---|---|---|---|
| RCS | 01 | 01 | 01 | 01 | 10 | 10 | 10 | 10 | 10 | 10 | 10 | 10 | 10 | 10 | 10 | 10 |

The following TABLE 2 lists a relay control signal sequence to activate each signal path between adapter connector 525 and RJ45 jack 562(2) in accordance with FIG. 35 and to deactivate each signal path between adapter connector 525 and the remaining RJ45 jacks 562 in accordance with FIG. 36:

TABLE 2

| | 1-1 | 1-2 | 1-3 | 1-4 | 2-1 | 2-2 | 2-3 | 2-4 | 3-1 | 3-2 | 3-3 | 3-4 | 4-1 | 4-2 | 4-3 | 4-4 |
|---|---|---|---|---|---|---|---|---|---|---|---|---|---|---|---|---|
| RCS | 10 | 10 | 10 | 10 | 01 | 01 | 01 | 01 | 10 | 10 | 10 | 10 | 10 | 10 | 10 | 10 |

The following TABLE 3 lists a relay control signal sequence to activate each signal path between adapter connector 525 and RJ45 jack 562(3) in accordance with FIG. 35 and to deactivate each signal path between adapter connector 525 and the remaining RJ45 jacks 562 in accordance with FIG. 36:

TABLE 3

| | 1-1 | 1-2 | 1-3 | 1-4 | 2-1 | 2-2 | 2-3 | 2-4 | 3-1 | 3-2 | 3-3 | 3-4 | 4-1 | 4-2 | 4-3 | 4-4 |
|---|---|---|---|---|---|---|---|---|---|---|---|---|---|---|---|---|
| RCS | 10 | 10 | 10 | 10 | 10 | 10 | 10 | 10 | 01 | 01 | 01 | 01 | 10 | 10 | 10 | 10 |

The following TABLE 4 lists a relay control signal sequence to activate each signal path between adapter connector 525 and RJ45 jack 562(4) in accordance with FIG. 35 and to deactivate each signal path between adapter connector 525 and the remaining RJ45 jacks 562 in accordance with FIG. 36:

TABLE 4

| | 1-1 | 1-2 | 1-3 | 1-4 | 2-1 | 2-2 | 2-3 | 2-4 | 3-1 | 3-2 | 3-3 | 3-4 | 4-1 | 4-2 | 4-3 | 4-4 |
|---|---|---|---|---|---|---|---|---|---|---|---|---|---|---|---|---|
| RCS | 10 | 10 | 10 | 10 | 10 | 10 | 10 | 10 | 10 | 10 | 10 | 10 | 01 | 01 | 01 | 01 |

A first set of alien cross-talk testing transmission signal paths consists of a signal path from testing connection node TCN-1 of adapter connector 525 through layers 536 and 537 to cable connection nodes 1-1 of a RJ45 jack 562(1), a signal path from testing connection node TCN-1 of adapter connector 525 through layers 536 and 537 to cable connection node 1-2 of RJ45 jack 562(1), a signal path from testing connection node TCN-1 of adapter connector 525 through layers 536 and 537 to a cable connection node 1-3 of a RJ45 jack 562(1) and a signal path from testing connection node TCN-1 of adapter connector 525 through layers 536 and 537 to a cable connection node 1-4 of RJ45 jack 562(1).

A first set of alien cross-talk testing reception signal paths consists of a signal path from testing connection node TCN-4 of adapter connector 525 through layers 536 and 537 to cable connection nodes 1-1 of a RJ45 jack 562(1), a signal path from testing connection node TCN-4 of adapter connector 525 through layers 536 and 537 to cable connection node 1-2 of RJ45 jack 562(1), a signal path from testing connection node TCN-4 of adapter connector 525 through layers 536 and 537 to a cable connection node 1-3 of a RJ45 jack 562(1) and a signal path from testing connection node TCN-4 of adapter connector 525 through layers 536 and 537 to a cable connection node 1-4 of RJ45 jack 562(1).

A second set of alien cross-talk testing transmission signal paths consists of a signal path from testing connection node TCN-1 of adapter connector 525 through layers 536 and 537 to cable connection nodes 2-1 of a RJ45 jack 562(2), a signal path from testing connection node TCN-1 of adapter connector 525 through layers 536 and 537 to cable connection node 2-2 of RJ45 jack 562(2), a signal path from testing connection node TCN-1 of adapter connector 525 through layers 536 and 537 to a cable connection node 2-3 of a RJ45 jack 562(2) and a signal path from testing connection node TCN-1 of adapter connector 525 through layers 536 and 537 to a cable connection node 2-4 of RJ45 jack 562(2).

A second set of alien cross-talk testing reception signal paths consists of a signal path from testing connection node TCN-4 of adapter connector 525 through layers 536 and 537 to cable connection nodes 2-1 of a RJ45 jack 562(2), a signal path from testing connection node TCN-4 of adapter connector 525 through layers 536 and 537 to cable connection node 2-2 of RJ45 jack 562(2), a signal path from testing connection node TCN-4 of adapter connector 525 through layers 536 and 537 to a cable connection node 2-3 of a RJ45 jack 562(2) and a signal path from testing connection node TCN-4 of adapter connector 525 through layers 536 and 537 to a cable connection node 2-4 of RJ45 jack 562(2).

A third set of alien cross-talk testing transmission signal paths consists of a signal path from testing connection node TCN-1 of adapter connector 525 through layers 536 and 537 to cable connection nodes 3-1 of a RJ45 jack 562(3), a signal path from testing connection node TCN-1 of adapter connector 525 through layers 536 and 537 to cable connection node 3-2 of RJ45 jack 562(3), a signal path from testing connection node TCN-1 of adapter connector 525 through layers 536 and 537 to a cable connection node 3-3 of a RJ45 jack 562(3) and a signal path from testing connection node TCN-1 of adapter connector 525 through layers 536 and 537 to a cable connection node 3-4 of RJ45 jack 562(3).

A third set of alien cross-talk testing reception signal paths consists of a signal path from testing connection node TCN-4 of adapter connector 525 through layers 536 and 537 to cable connection nodes 3-1 of a RJ45 jack 562(3), a signal path from testing connection node TCN-4 of adapter connector 525 through layers 536 and 537 to cable connection node 3-2 of RJ45 jack 562(3), a signal path from testing connection node TCN-4 of adapter connector 525 through layers 536 and 537 to a cable connection node 3-3 of a RJ45 jack 562(3) and a signal path from testing connection node TCN-4 of adapter connector 525 through layers 536 and 537 to a cable connection node 3-4 of RJ45 jack 562(3).

A fourth set of alien cross-talk testing transmission signal paths consists of a signal path from testing connection node TCN-1 of adapter connector 525 through layers 536 and 537 to cable connection nodes 4-1 of a RJ45 jack 562(4), a signal path from testing connection node TCN-1 of adapter connector 525 through layers 536 and 537 to cable connection node 4-2 of RJ45 jack 562(4), a signal path from testing connection node TCN-1 of adapter connector 525 through layers 536 and 537 to a cable connection node 4-3 of a RJ45 jack 562(4) and a signal path from testing connection node TCN-1 of adapter connector 525 through layers 536 and 537 to a cable connection node 4-4 of RJ45 jack 562(4).

A fourth set of alien cross-talk testing reception signal paths consists of a signal path from testing connection node TCN-4 of adapter connector 525 through layers 536 and 537 to cable connection nodes 4-1 of a RJ45 jack 562(4), a signal path from testing connection node TCN-4 of adapter connector 525 through layers 536 and 537 to cable connection node 4-2 of RJ45 jack 562(4), a signal path from testing connection node TCN-4 of adapter connector 525 through layers 536 and 537 to a cable connection node 4-3 of a RJ45 jack 562(4) and a signal path from testing connection node TCN-4 of adapter connector 525 through layers 536 and 537 to a cable connection node 4-4 of RJ45 jack 562(4).

For alien cross-talk testing, the switch control signals and the relay control signals are used to selectively activate and deactivate each of the aforementioned signal paths. Specifically, the following TABLE 5 list a switch control sequence and four (4) relay control signal sequences for an alien cross-talk testing scheme utilizing the alien cross-talk testing transmission signal paths of RJ45 jack 562(1) and the alien cross-talk testing reception signal paths of RJ45 jacks

TABLE 5

| | 1-1 | 1-2 | 1-3 | 1-4 | 2-1 | 2-2 | 2-3 | 2-4 | 3-1 | 3-2 | 3-3 | 3-4 | 4-1 | 4-2 | 4-3 | 4-4 |
|---|---|---|---|---|---|---|---|---|---|---|---|---|---|---|---|---|
| SCS | 01 | | | | 10 | | | | 10 | | | | 10 | | | |
| RCS(1) | 11 | 10 | 10 | 10 | 11 | 10 | 10 | 10 | 11 | 10 | 10 | 10 | 11 | 10 | 10 | 10 |
| RCS(2) | 10 | 11 | 10 | 10 | 10 | 11 | 10 | 10 | 10 | 11 | 10 | 10 | 10 | 11 | 10 | 10 |
| RCS(3) | 10 | 10 | 11 | 10 | 10 | 10 | 11 | 10 | 10 | 10 | 11 | 10 | 10 | 10 | 11 | 10 |
| RCS(4) | 10 | 10 | 10 | 11 | 10 | 10 | 10 | 11 | 10 | 10 | 10 | 11 | 10 | 10 | 10 | 11 |

Also by example, the following TABLE 6 list a switch control sequence and four (4) relay control signal sequences for an alien cross-talk testing scheme utilizing the alien cross-talk testing transmission signal paths of RJ45 jack 562(2) and the alien cross-talk testing reception

TABLE 6

| | 1-1 | 1-2 | 1-3 | 1-4 | 2-1 | 2-2 | 2-3 | 2-4 | 3-1 | 3-2 | 3-3 | 3-4 | 4-1 | 4-2 | 4-3 | 4-4 |
|---|---|---|---|---|---|---|---|---|---|---|---|---|---|---|---|---|
| SCS | 10 | | | | 11 | | | | 10 | | | | 10 | | | |
| RCS(1) | 11 | 10 | 10 | 10 | 11 | 10 | 10 | 10 | 11 | 10 | 10 | 10 | 11 | 10 | 10 | 10 |
| RCS(2) | 10 | 11 | 10 | 10 | 10 | 11 | 10 | 10 | 10 | 11 | 10 | 10 | 10 | 11 | 10 | 10 |
| RCS(3) | 10 | 10 | 11 | 10 | 10 | 10 | 11 | 10 | 10 | 10 | 11 | 10 | 10 | 10 | 11 | 10 |
| RCS(4) | 10 | 10 | 10 | 11 | 10 | 10 | 10 | 11 | 10 | 10 | 10 | 11 | 10 | 10 | 10 | 11 |

Also by example, the following TABLE 7 list a switch control sequence and four (4) relay control signal sequences for an alien cross-talk testing scheme utilizing the alien cross-talk testing transmission signal paths of RJ45 jack 562(3) and the alien cross-talk testing reception signal paths of RJ45 jacks 562(1), 562(2) and 562(4):

TABLE 7

| | 1-1 | 1-2 | 1-3 | 1-4 | 2-1 | 2-2 | 2-3 | 2-4 | 3-1 | 3-2 | 3-3 | 3-4 | 4-1 | 4-2 | 4-3 | 4-4 |
|---|---|---|---|---|---|---|---|---|---|---|---|---|---|---|---|---|
| SCS | 10 | | | | 10 | | | | 01 | | | | 10 | | | |
| RCS(1) | 11 | 10 | 10 | 10 | 11 | 10 | 10 | 10 | 11 | 10 | 10 | 10 | 11 | 10 | 10 | 10 |
| RCS(2) | 10 | 11 | 10 | 10 | 10 | 11 | 10 | 10 | 10 | 11 | 10 | 10 | 10 | 11 | 10 | 10 |
| RCS(3) | 10 | 10 | 11 | 10 | 10 | 10 | 11 | 10 | 10 | 10 | 11 | 10 | 10 | 10 | 11 | 10 |
| RCS(4) | 10 | 10 | 10 | 11 | 10 | 10 | 10 | 11 | 10 | 10 | 10 | 11 | 10 | 10 | 10 | 11 |

Also by example, the following TABLE 8 list a switch control sequence and four (4) relay control signal sequences for an alien cross-talk testing scheme utilizing the alien cross-talk testing transmission signal paths of RJ45 jack 562(4) and the alien cross-talk testing reception signal paths of RJ45 jacks 562(1), 562(2) and 562(3):

TABLE 8

| | 1-1 | 1-2 | 1-3 | 1-4 | 2-1 | 2-2 | 2-3 | 2-4 | 3-1 | 3-2 | 3-3 | 3-4 | 4-1 | 4-2 | 4-3 | 4-4 |
|---|---|---|---|---|---|---|---|---|---|---|---|---|---|---|---|---|
| SCS | 10 | | | | 10 | | | | 10 | | | | 01 | | | |
| RCS(1) | 11 | 10 | 10 | 10 | 11 | 10 | 10 | 10 | 11 | 10 | 10 | 10 | 11 | 10 | 10 | 10 |
| RCS(2) | 10 | 11 | 10 | 10 | 10 | 11 | 10 | 10 | 10 | 11 | 10 | 10 | 10 | 11 | 10 | 10 |
| RCS(3) | 10 | 10 | 11 | 10 | 10 | 10 | 11 | 10 | 10 | 10 | 11 | 10 | 10 | 10 | 11 | 10 |
| RCS(4) | 10 | 10 | 10 | 11 | 10 | 10 | 10 | 11 | 10 | 10 | 10 | 11 | 10 | 10 | 10 | 11 |

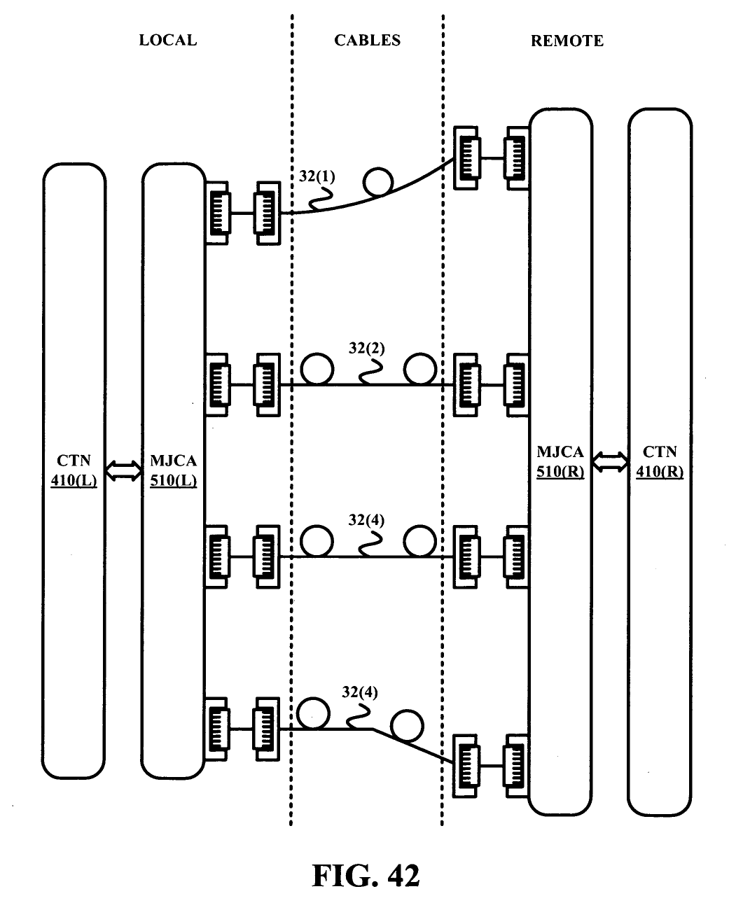

A description of an exemplary cable testing environments will now be provided herein to facilitate an understanding of a multi-cable testing and an alien cross-talk cable testing of four (4) cables 32 in accordance with the present invention. In all of the exemplary alien cross-talk environments shown in FIGS. 42, 44, 46 and 52, the M number of wires pairs for each cable is four (4), each cable tester 410 and multi-cable jack adapter 510 is made in accordance with the teachings of FIGS. 27-41, and each alien cross-talk test signal unit 62 is made in accordance with FIGS. 3-26.

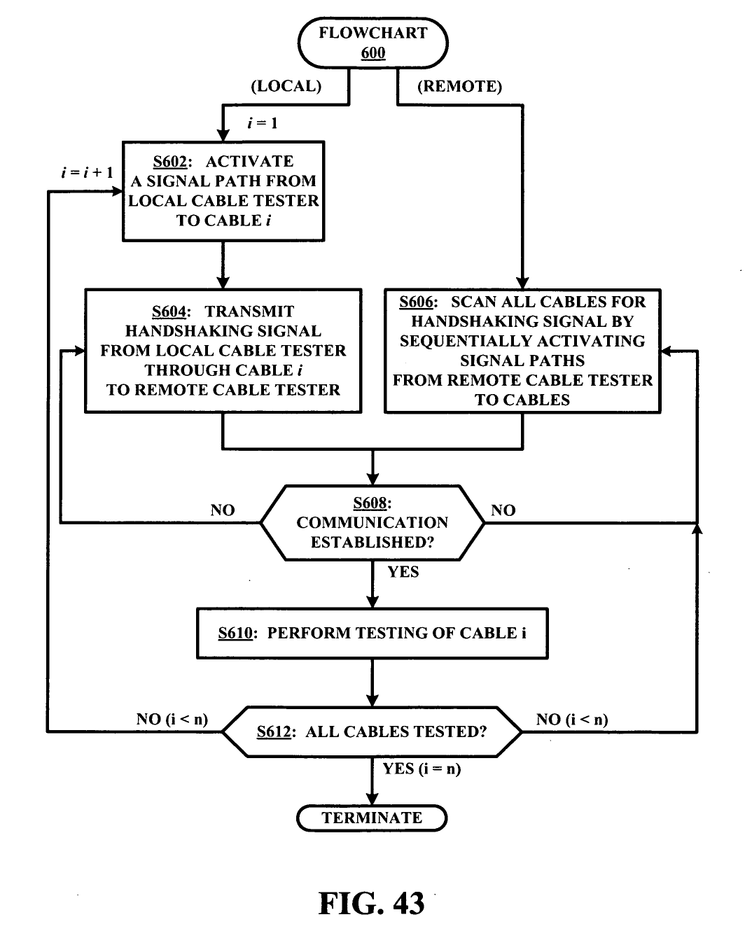

Referring to FIG. 42, a local cable tester (“CT”) 410(L) is connected to a local multi-jack cable adapter (“MJCA”) 510(L), which is further connected to a local end of each cable 32, and a remote cable tester (“CT”) 410(R) is connected to a remote multi-jack cable adapter (“MJCA”) 510(R), which is further connected to a remote end of each cable 32. Cable testers 410 implement a multi-cable testing method in accordance with a flowchart 600 as illustrated FIG. 43.

Prior to an execution of flowchart 600, an operator makes all of the connections shown in FIG. 42. Thereafter, a stage S602 of flowchart 600 encompasses a switch control module of local cable tester 410(L) transmitting a command to a switch controller of local multi-jack cable adapter 510(L) to activate all of the multi-cable testing signal paths from local cable tester 410(L) through local multi-jack cable adapter 510(L) to cable 32(1) and to deactivate all of the signal paths from local cable tester 410(L) through local multi-jack cable adapter 510(L) to cables 32(2)-32(4), and a stage S604 of flowchart 600 encompasses local cable tester 410(L) transmitting a handshaking signal through cable 32(1) to remote cable tester 410(R) via the activated multi-cable testing signal paths. Concurrently,.a stage S606 of flowchart 600 encompasses remote cable tester 410(R) scanning all of the cables 32 for the handshaking signal by sequentially and continually activating one set of multi-cable testing signal paths from remote cable tester 410(R) to cables 32 while deactivating the remaining sets of signal paths from remote cable tester 410(4) to cables 32.

A stage S608 of flowchart 600 consists of cable testers 410 execution of respective stages S604 and S606 until such time a communication is established between cable testers 410 via the handshaking signal. A stage S610 of flowchart 600 encompasses cable testers 410 performing normal testing procedures on cable 32(1) as would be appreciated by those having ordinary skill in the art. Upon completion, in accordance with stage S612, cable testers 410 will return to respective stages S602 and S606 to test cables 32(2), 32(3) and 32(4) in the manner by which cable 32(1) was tested. Those having ordinary skill in the art will appreciate the efficient and quick manner by which the operator was able to test all four (4) cables 32 in view of the elimination of a requirement for the operator to individually connect a cable 32 to cable testers 410 for testing and to disconnect the cable from cable testers 410 to thereby connect another cable 32 for testing.

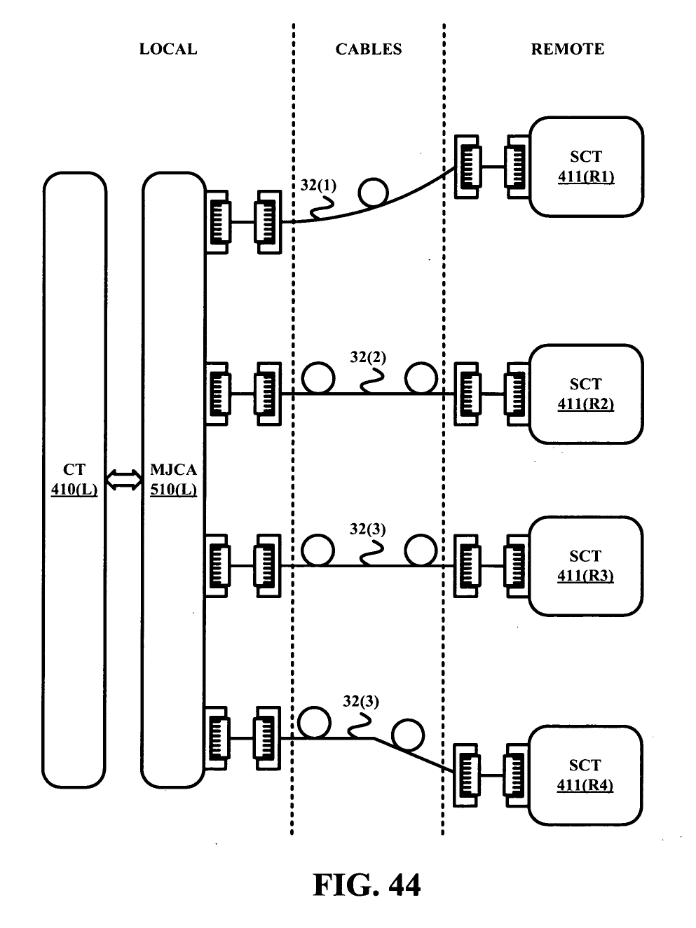

Referring to FIG. 44, a local cable testing unit (“CT”) 410(L) is connected to a local multi-jack cable adapter (“MJCA”) 510(L), which is further connected to a local end of each cable 32. On a remote end of each cable 32 is connected a standard remote cable tester (“SCT”) 411 (e.g., a DualRemote as sold by Agilent). Cable testers 410 and 411 implement a multi-cable testing method in accordance with a flowchart 620 as illustrated FIG. 43.

Prior to an execution of flowchart 620, an operator makes the all of the local connections shown in FIG. 42 and the remote connection of remote cable tester 411 (R) to cable 32(1). Thereafter, a stage S622 of flowchart 620 encompasses a switch control module of local cable tester 410(L) transmitting a command to a switch controller of local multi-jack cable adapter 510(L) to activate all of the multi-cable testing signal paths from local cable tester 410(L) through local multi-jack cable adapter 510(L) to cable 32(1) and to deactivate all of the signal paths from local cable tester 410(L) through local multi-jack cable adapter 510(L) to cables 32(2)-32(4), and a stage S624 of flowchart 620 encompasses local cable tester 410(L) transmitting a handshaking signal through cable 32(1) to remote cable tester 411(R1) via the activated multi-cable testing signal paths. Concurrently, a stage S626 of flowchart 620 encompasses remote cable tester 411(R1) scanning cable 32(1) for the handshaking signal.

A stage S628 of flowchart 620 consists of local cable tester 410(L) and remote cable tester 411(R1) execution of respective stages S624 and S626 until such time a communication is established between local cable tester 410(L) and remote cable tester 411(R1) via the handshaking signal. A stage S630 of flowchart 620 encompasses local cable tester 410(L) and remote cable tester 411(R1) performing normal testing procedures on cable 32(1) as would be appreciated by those having ordinary skill in the art. Upon completion, in accordance with stage S632, remote cable tester 32(1) will be disconnected from cable 32(1), local cable tester 410(L) will return to stage S626 and remote cable tester 32(2) will be connected to cable 32(2) to test cable 32(2) in the manner by which cable 32(1) was tested. This is repeated for testing of cables 32(3) and 32(4. Those having ordinary skill in the art will appreciate the manner by which the operator is able to test all four (4) cables 32 with the elimination of a requirement for the operator to individually connect a cable 32 under test to local cable tester 410(L) and to disconnect the cable from cable testers 410 to thereby connect another cable 32 for testing.

Referring to FIGS. 42-45, those having ordinary skill in the art will appreciate how to apply the inventive principles of the multi-cable testing environments illustrated in FIGS. 42 and 44 to hybrids multi-testing cable environments.

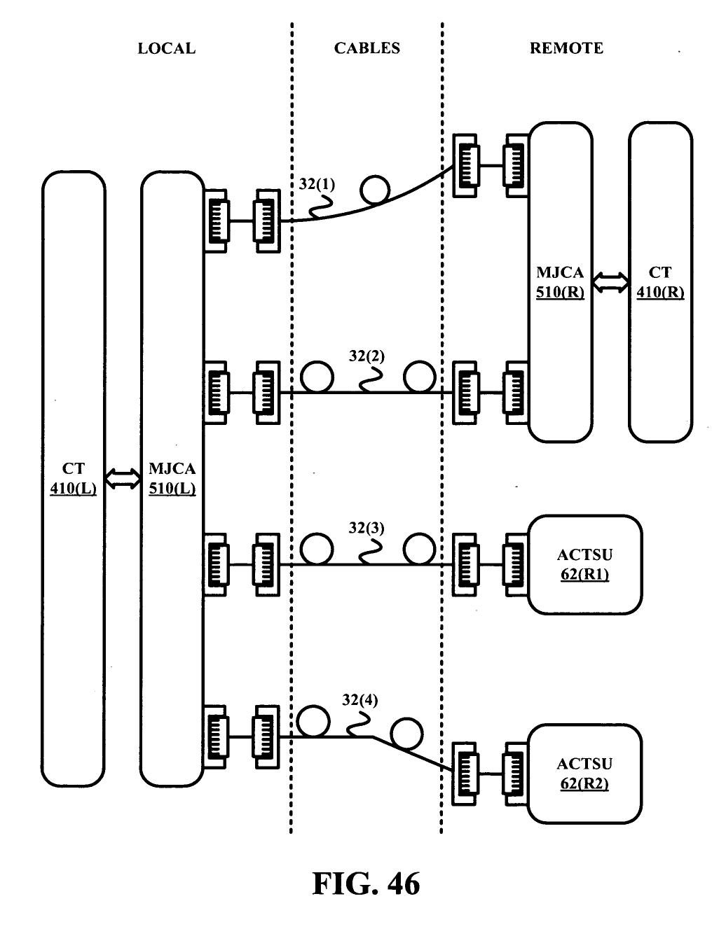

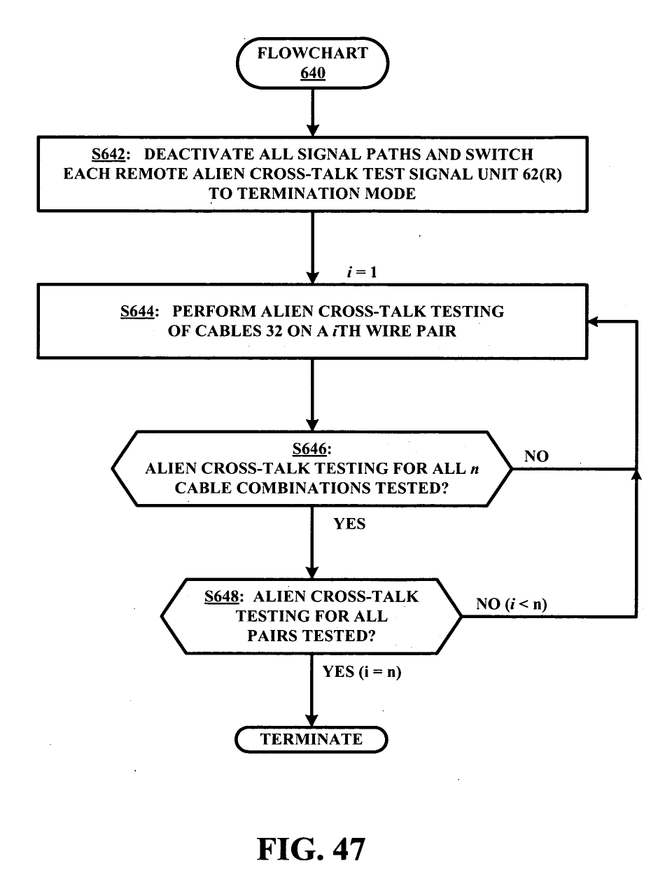

Referring to FIG. 46, a local cable testing unit (“CT”) 410(L) is connected to a local multi-jack cable adapter (“MJCA”) 510(L), which is further connected to a local end of each cable 32, and a remote cable testing unit (“CT”) 410(R) is connected to a remote multi-jack cable adapter (“MJCA”) 510(R), which is further connected to remote ends of cables 32(1) and 32(2); A remote alien cross-talk test signal unit (“ACTSU”) 62(R1) is connected to a remote end of cable 32(3) and a remote alien cross-talk test signal unit (“ACTSU”) 62(R2) is connected to a remote end of cable 32(4). Cables testing units 410 implement an alien cross-talk testing method in accordance with a flowchart 640 as illustrated FIG. 47.

A stage S640 of flowchart 640 encompasses a deactivating all signal paths between local cable tester 410(L) and cables 32 and remote cable tester 410(R) and cables 32(1) and 32(2). Stages S640 further encompasses a switch of each remote alien cross-talk test signal unit 62(R) to a termination mode. Stages S644 and S646 of flowchart 640 encompasses a performance of alien cross-talk testing of cables 32 on ith wire pair for each cable 32 whereby stages S644 and S646 are repeated until all wire pairs have been tested in accordance with a stage S648 of flowchart 640.

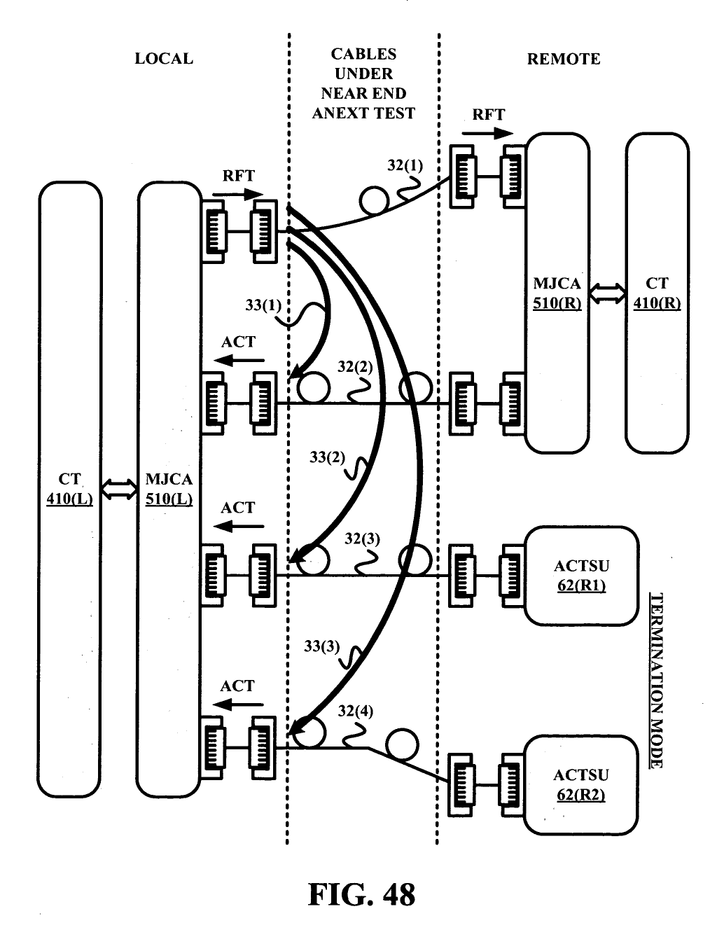

In the context of a near end ANEXT test as shown in FIG. 48, local cable tester 410(L) activates an alien cross-talk transmission signal path to the 1^{st} wire pair of cable 32(1) and remote cable tester 410(R) activates an alien cross-talk reception signal path to the 1^{st} wire pair of cable 32(1) whereby a RF test signal (“RFT”) is transmitted from local cable tester 410(L) to remote cable tester 410(R) to thereby set cable 32(1) as a disturber cable. To test for alien cross-talk, local cable tester 410(L) first activates an alien cross-talk reception signal path to the 1^{st} wire pair of cable 32(2) to thereby test the alien cross-talk coupling 33(1) of cable 32(1) to cable 32(2). Second, local cable tester 410(L) deactivates the an alien cross-talk reception signal path to the 1^{st} wire pair of cable 32(2) and activates the an alien cross-talk reception signal path to the 1^{st} wire pair of cable 32(3) to thereby test the alien cross-talk coupling 33(2) of cable 32(1) to cable 32(3). Finally, local cable tester 410(L) deactivates the an alien cross-talk reception signal path to the 1^{st} wire pair of cable 32(3) and activates the an alien cross-talk reception signal path to the 1^{st} wire pair of cable 32(4) to thereby test the alien cross-talk coupling 33(3) of cable 32(1) to cable 32(4). This wire by wire testing phase is repeated for the 2^{nd}, 3^{rd} and 4^{th} wire pairs of cables 32. Furthermore, the entire testing can be repeated three (3) more times whereby cables 32(2), 32(3) and 32(4) are sequentially set as the disturber cable for the testing.

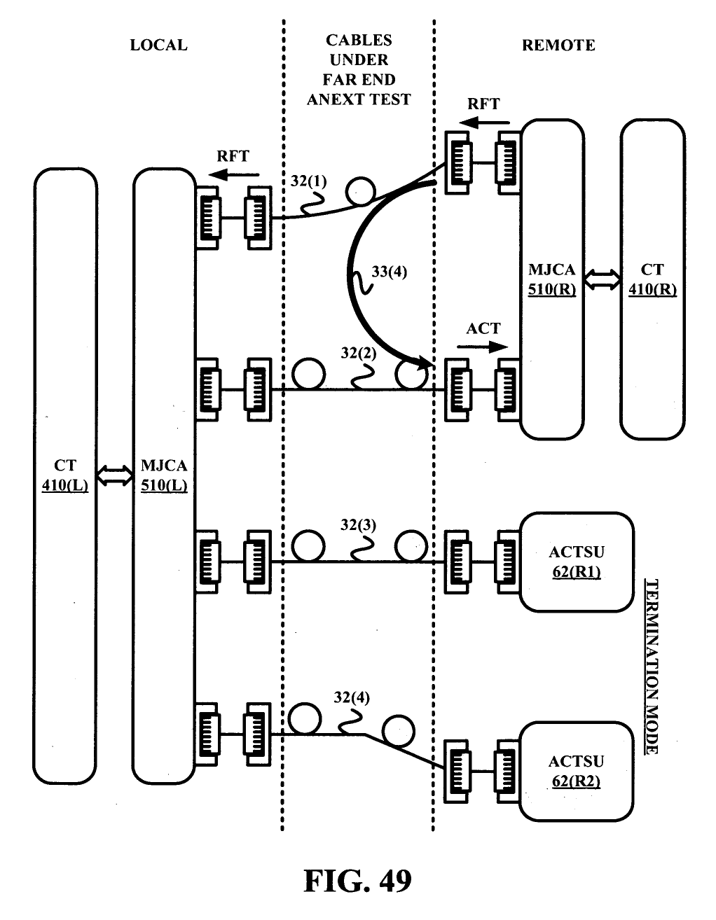

In the context of a far end ANEXT test as shown in FIG. 49, remote cable tester 410(R) activates an alien cross-talk transmission signal path to the 1^{st} wire pair of cable 32(1) and local cable tester 410(L) activates an alien cross-talk reception signal path to the 1^{st} wire pair of cable 32(1) whereby a RF test signal (“RFT”) is transmitted from remote cable tester 410(R) to local cable tester 410(L) to thereby set cable 32(1) as a disturber cable. To test for alien cross-talk, remote cable tester 410(R) activates an alien cross-talk reception signal path to the 1^{st} wire pair of cable 32(2) to thereby test the alien cross-talk coupling 33(4) of cable 32(1) to cable 32(2). This wire by wire testing phase is repeated for the 2^{nd}, 3^{rd} and 4^{th} wire pairs of cables 32.

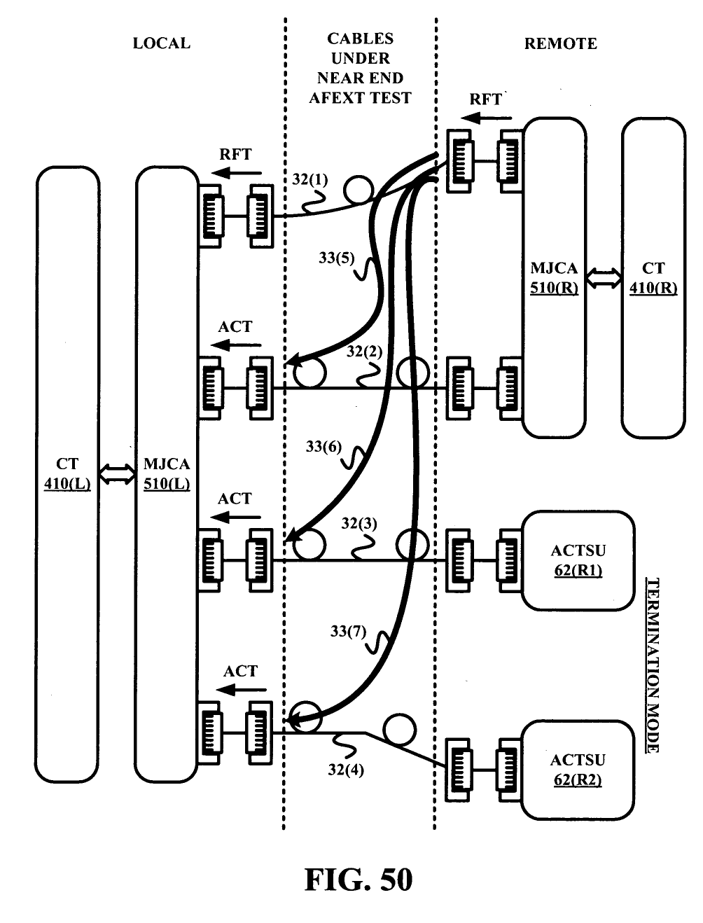

In the context of a near end AFEXT test as shown in FIG. 50, remote cable tester 410(R) activates an alien cross-talk transmission signal path to the 1^{st} wire pair of cable 32(1) and local cable tester 410(L) activates an alien cross-talk reception signal path to the 1^{st} wire pair of cable 32(1) whereby a RF test signal (“RFT”) is transmitted from remote cable tester 410(R) to local cable tester 410(L) to thereby set cable 32(1) as a disturber cable. To test for alien cross-talk, local cable tester 410(L) first activates an alien cross-talk reception signal path to the 1^{st} wire pair of cable 32(2) to thereby test the alien cross-talk coupling 33(5) of cable 32(1) to cable 32(2). Second, local cable tester 410(L) deactivates the an alien cross-talk reception signal path to the 1^{st} wire pair of cable 32(2) and activates the an alien cross-talk reception signal path to the 1^{st} wire pair of cable 32(3) to thereby test the alien cross-talk coupling 33(6) of cable 32(1) to cable 32(3). Finally, local cable tester 410(L) deactivates the an alien cross-talk reception signal path to the 1^{st} wire pair of cable 32(3) and activates the an alien cross-talk reception signal path to the 1^{st} wire pair of cable 32(4) to thereby test the alien cross-talk coupling 33(7) of cable 32(1) to cable 32(4). This wire by wire testing phase is repeated for the 2^{nd}, 3^{rd} and 4^{th} wire pairs of cables 32. Furthermore, the entire testing can be repeated three (3) more times whereby cables 32(2), 32(3) and 32(4) are sequentially set as the disturber cable for the testing.

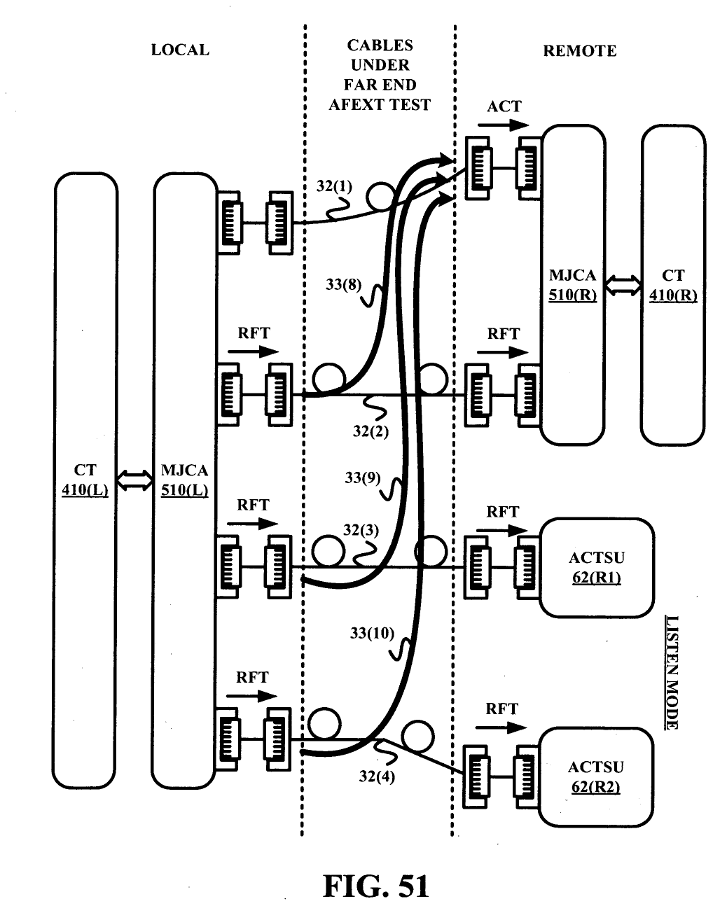

In the context of a far end AFEXT test as shown in FIG. 51, local cable tester 410(L) deactivates an alien cross-talk transmission path to the 1^{st} wire pair of cable 32(1) and remote cable tester 410(R) activates an alien cross-talk reception signal path to the 1^{st} wire pair of cable 32(1) to thereby set cable 32(1) as a victim cable. To test for alien cross-talk, local cable tester 410(L) first activates an alien cross-talk transmission signal path to the 1^{st} wire pair of cable 32(2) and remote cable tester 410(R) first activates an alien cross-talk reception signal path to the 1^{st} wire pair of cable 32(2) to thereby test the alien cross-talk coupling 33(8) of cable 32(2) to cable 32(1). Second, local cable tester 410(L) and remote cable tester 410(R) deactivate the respective alien cross-talk reception signal paths to the 1^{st} wire pair of cable 32(2), local cable tester 410(L) activates the an alien cross-talk transmission signal path to the 1^{st} wire pair of cable 32(3) and alien cross-talk test signal unit 62(R1) is set to the listen mode to thereby test the alien cross-talk coupling 33(9) of cable 32(3) to cable 32(1). Finally, local cable tester 410(L) deactivates the alien cross-talk reception signal path to the 1^{st} wire pair of cable 32(3), local cable tester 410(L) activates an alien cross-talk transmission signal path to the 1^{st} wire pair of cable 32(4) and alien cross-talk test signal unit 62(R2) is set to the listen mode to thereby test the alien cross-talk coupling 33(10) of cable 32(4) to cable 32(1). This wire by wire testing phase is repeated for the 2^{nd}, 3^{rd} and 4^{th} wire pairs of cables 32. Furthermore, the entire testing can be repeated three (3) more times whereby cables 32(2), 32(3) and 32(4) are set as the disturber cable for a different test.

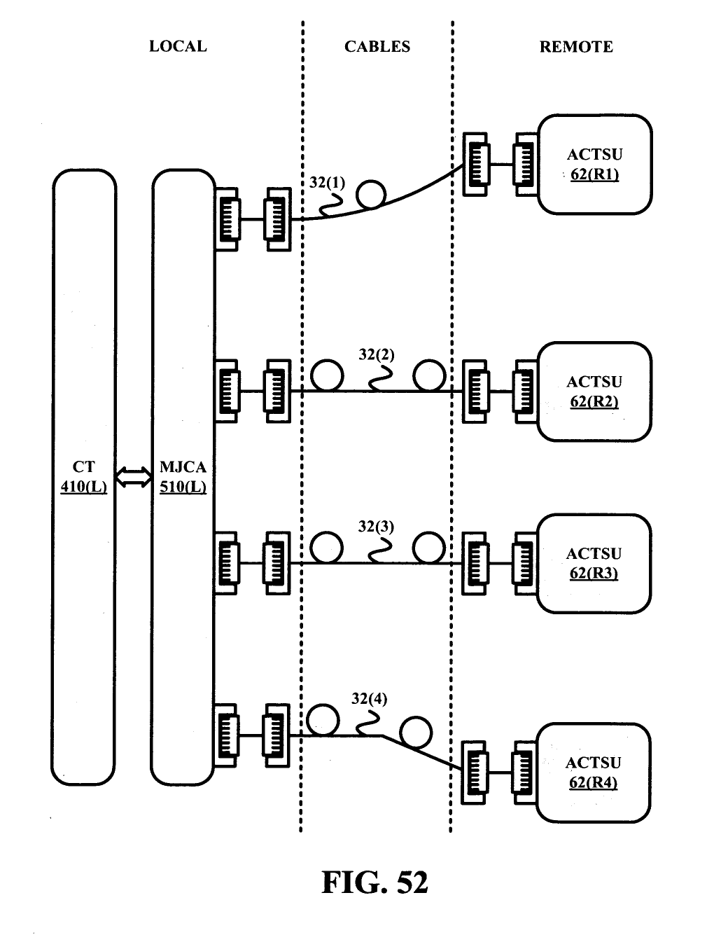

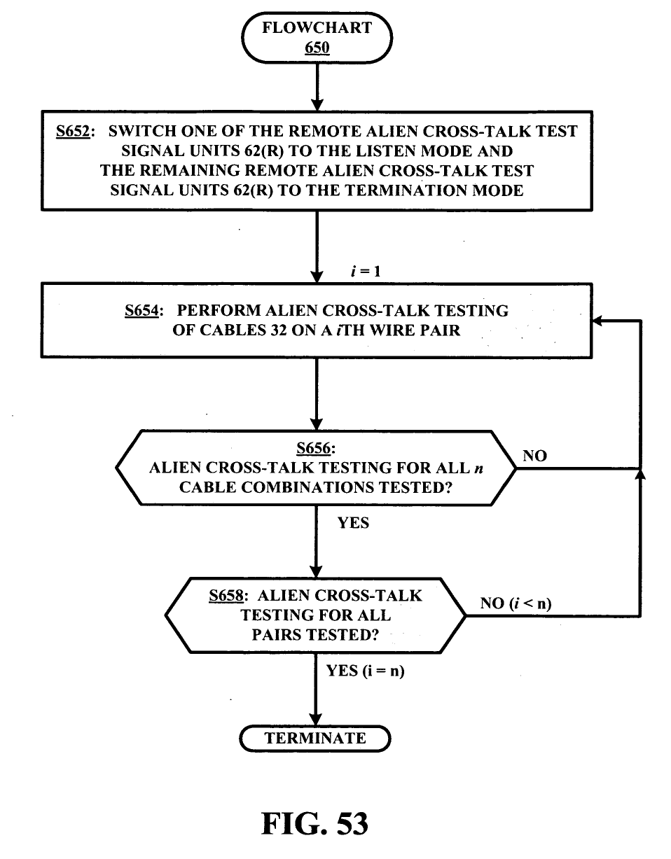

Referring to FIG. 52, a local cable testing unit (“CT”) 410(L) is connected to a local multi-jack cable adapter (“MJCA”) 510(L), which is further connected to a local end of each cable 32. A remote alien cross-talk test signal unit (“ACTSU”) 62(R1) is connected to a remote end of cable 32(1), a remote alien cross-talk test signal unit (“ACTSU”) 62(R2) is connected to a remote end of cable 32(2), a remote alien cross-talk test signal unit (“ACTSU”) 62(R3) is connected to a remote end of cable 32(3) and a remote alien cross-talk test signal unit (“ACTSU”) 62(R4) is connected to a remote end of cable 32(4). Cables testing unit 410 implement an alien cross-talk testing method in accordance with a flowchart 650 as illustrated FIG. 53.

A stage S650 of flowchart 650 encompasses switching remote alien cross-talk test signal unit 62(R1) to a listen mode. Stage S650 further encompasses a switch of remote alien cross-talk test signal unit 62(R2)-62(R4) to a termination mode. Stages S654 and S656 of flowchart 650 encompasses a performance of alien cross-talk testing of cables 32 on ith wire pair for each cable 32 whereby stages S654 and S656 are repeated until all wire pairs have been tested in accordance with a stage S658 of flowchart 650.

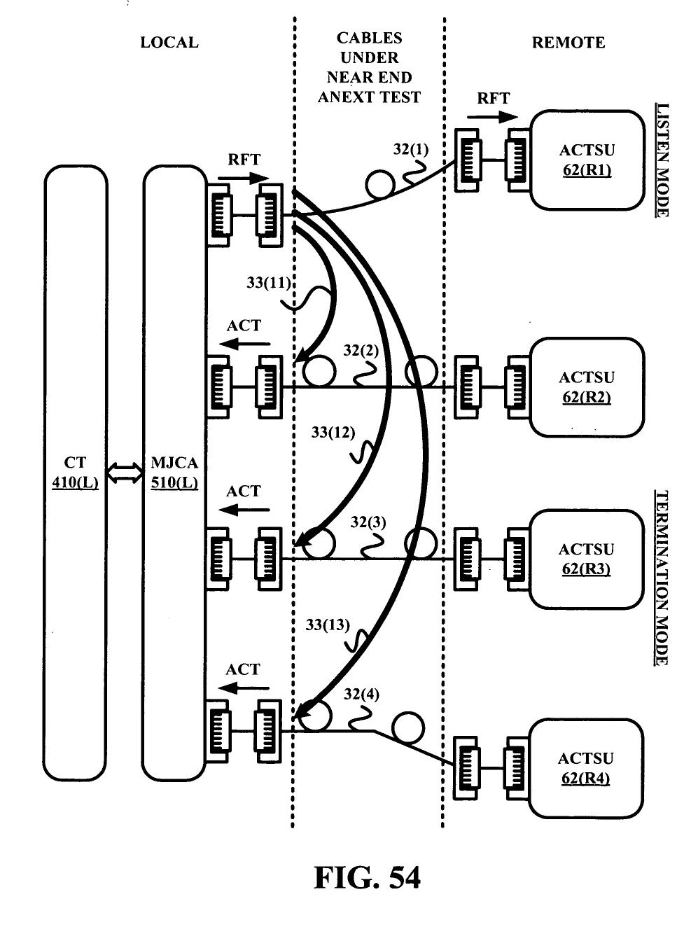

In the context of a near end ANEXT test as shown in FIG. 54, local cable tester 410(L) activates an alien cross-talk transmission signal path to the 1^{st} wire pair of cable 32(1) and whereby a RF test signal (“RFT”) is transmitted from local cable tester 410(L) to alien cross-talk test signal unit 62(R1) to thereby set cable 32(1) as a disturber cable. To test for alien cross-talk, local cable tester 410(L) first activates an alien cross-talk reception signal path to the 1^{st} wire pair of cable 32(2) to thereby test the alien cross-talk coupling 33(11) of cable 32(1) to cable 32(2). Second, local cable tester 410(L) deactivates the an alien cross-talk reception signal path to the 1^{st} wire pair of cable 32(2) and activates the an alien cross-talk reception signal path to the 1^{st} wire pair of cable 32(3) to thereby test the alien cross-talk coupling 33(12) of cable 32(1) to cable 32(3). Finally, local cable tester 410(L) deactivates the an alien cross-talk reception signal path to the 1^{st} wire pair of cable 32(3) and activates the an alien cross-talk reception signal path to the 1^{st} wire pair of cable 32(4) to thereby test the alien cross-talk coupling 33(13) of cable 32(1) to cable 32(4). This wire by wire testing phase is repeated for the 2^{nd}, 3^{rd} and 4^{th} wire pairs of cables 32. Furthermore, the entire testing can be repeated three (3) more times whereby cables 32(2), 32(3) and 32(4) are sequentially set as the disturber cable for the testing.

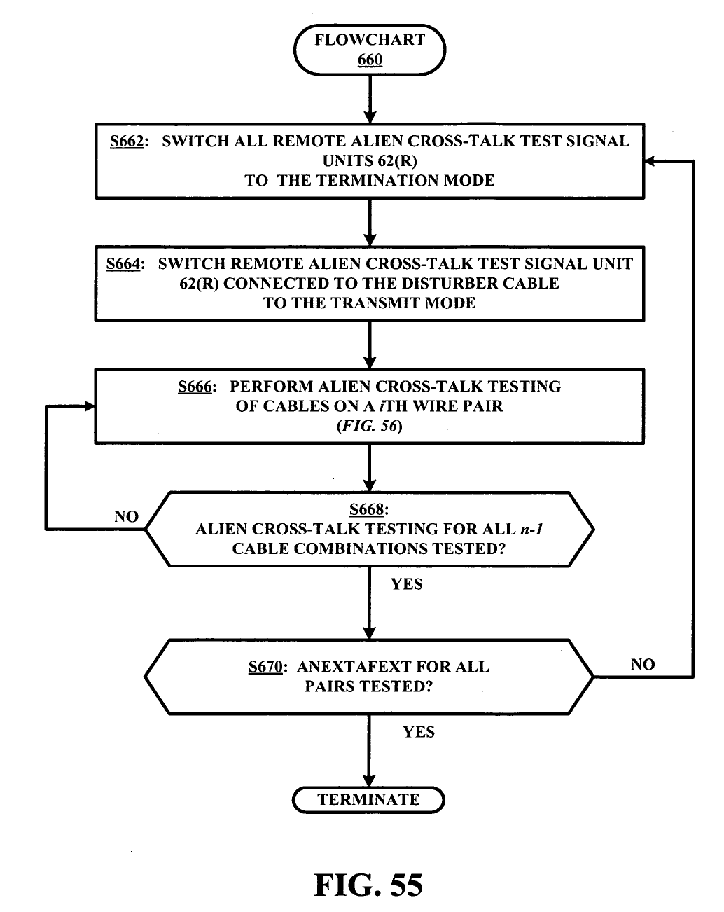

Referring to again to FIG. 52, cable testing unit 410 can also implement an alien cross-talk testing method in accordance with a flowchart 660 as illustrated FIG. 55.

A stage S660 of flowchart 660 encompasses switching all remote alien cross-talk test signal unit 62(R) to a termination mode, and stage S664 of flowchart 660 encompasses switching the remote alien cross-talk test signal unit 62(R1) to the transmit mode whereby cable 32(1) serves as a disturber cable. Stages S666 and S668 of flowchart 660 encompasses a performance of PSAFEXT testing of victim cable 32(2) whereby stages S666 and S668 are repeated for victim cables 32(3) and 32(4) in accordance with a stage S670 of flowchart 660.

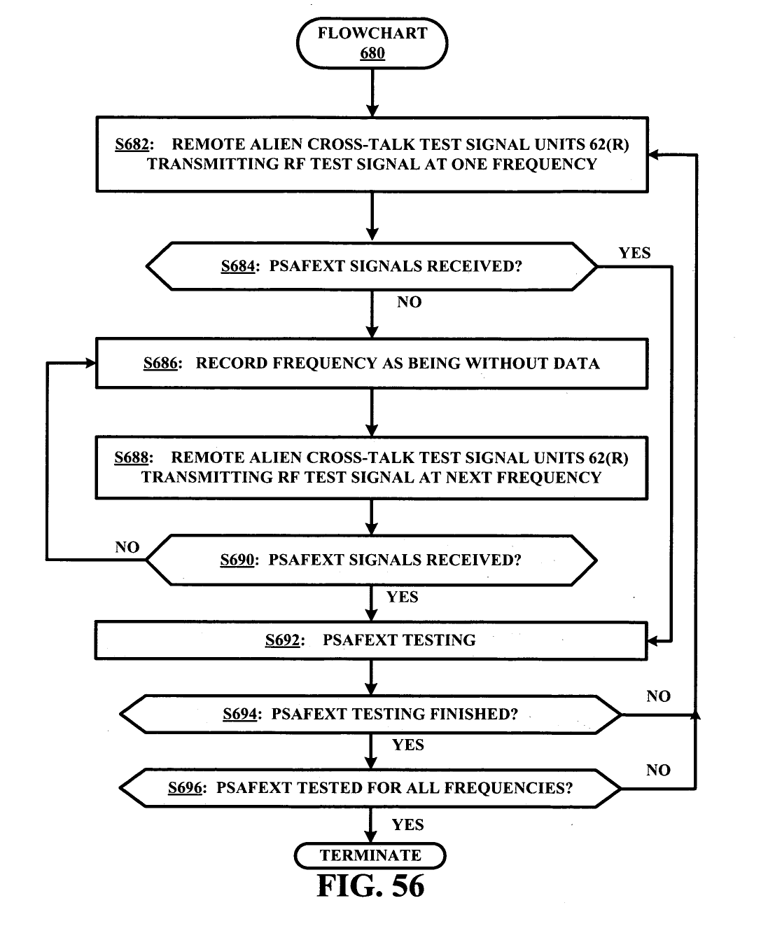

Remote alien cross-talk test signal unit 62(R1) is transmitting the RF test signal in the frequency sweep form illustrated in FIG. 23. As such, during stage S666, local cable tester 410(L) implements a frequency sweep testing method represented by a flowchart 680 illustrated in FIG. 56.

A stage S682 of flowchart 680 encompasses remote alien cross-talk test signal unit 62(R1) transmitting the RF test signal at one frequency, and a stage S684 of flowchart 680 encompasses local cable tester 410(L) determining whether it received PSAFEXT signals on any of the victim cables 32(2)-32(4). If so, then local cable tester 410(L) performs PSAFEXT testing during a stage S692 of flowchart 680 and returns to stage S682 to attempt to test the next frequency in accordance with stages S684 and S692.

Otherwise, local cable tester 410(L) records the frequency as being without data during a stage S686 of flowchart 680 and remote alien cross-talk test signal unit 62(R1) proceeds to transmit RF test signal at the next frequency. A stage S690 of flowchart 680 encompasses local cable tester 410(L) again determining whether it received PSAFEXT signals on any of the victim cables 32(2)-32(4). If so, then local cable tester 410(L) performs PSAFEXT testing for that frequency during stage S693 of flowchart 680 and returns to stage S682 to attempt to test the next frequency in accordance with stages S684 and S692. This cycle is repeated until all frequencies are eventually tested.

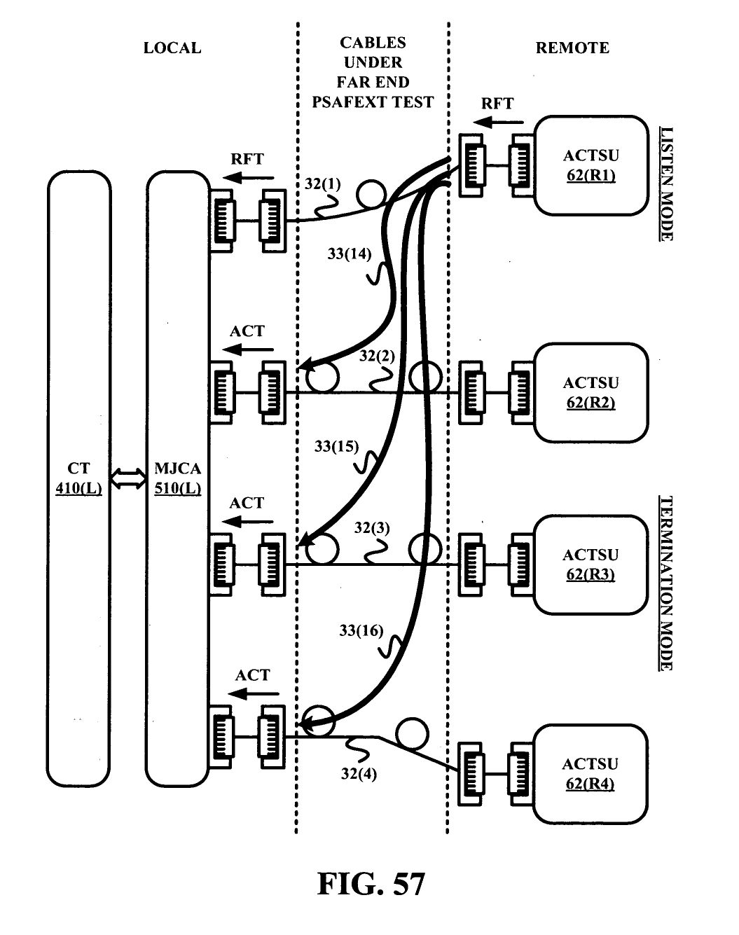

In the context of a PSAFEXT as shown in FIG. 57, local cable tester 410(L) will implement flowchart 660 (FIG. 55) and flowchart 680 (FIG. 56) for cables 32(2), 32(3) and 32(4) in sequence with each advancement in the sequence being premised on a complete testing of all frequencies as ensured by flowchart 680.

Referring to FIGS. 1-57, those having ordinary skill in the art will appreciate how to apply the inventive principles of the present invention to an alien cross-talk environment of the present invention having less than or more than four (4) wire pairs per cable, and/or having less than or more than three (3) disturber cables.

Referring to FIGS. 1-57, those having ordinary skill in the art will appreciate the numerous advantages of the present invention including, but not limited to, a complete, convenient, cost effective and expedient measurement of alien cross-talk on a victim cable.

While the embodiments of the invention disclosed herein are presently considered to be preferred, various changes and modifications can be made without departing from the scope of the invention. The scope of the invention is indicated in the appended claims and all changes that come within the meaning and range of equivalents are intended to be embraced therein.

1. A cable testing system, comprising:
a cable tester; and
a multi-jack cable adapter including:
a switch matrix operable to be in electrical communication with the cable tester and a plurality of cables to establish a plurality of signal paths between the cable tester and the plurality of cables; and
a switch controller operable to be in electrical communication with the switch matrix and the cable tester to control a switching by the switch matrix of each signal path between an activated state and a deactivated state as commanded by the cable tester.

2. The cable testing system of claim 1, wherein the activated state of a first signal path of the plurality of signal paths includes a multi-cable testing mode and an alien cross-talking testing mode.

3. The cable testing system of claim 2, wherein the alien cross-talking testing mode of the activated state includes a test signal transmission mode and a test signal reception mode.

4. The cable testing system of claim 1, wherein the deactivated state of a first signal path of the plurality of signal paths includes a test signal termination mode.

5. The cable testing system of claim 1,
wherein the activated state of a first signal path of the plurality of signal paths includes a multi-cable testing mode and an alien cross-talking testing mode;
wherein the deactivated state of the first signal path includes a test signal termination mode; and
wherein the switch matrix includes a first switch layer operable to switch the first signal path among the multi-cable testing mode, the alien cross-talk testing mode and the test signal termination mode.

6. The cable testing system of claim 5,
wherein the alien cross-talking testing mode of the activated state includes a test signal transmission mode and a test signal reception mode; and
wherein the switch matrix further includes a second switch layer operable to switch the first signal path between the test signal transmission mode and the test signal reception mode in response to the first signal path being switched to the alien cross-talk testing mode by the first switch layer.

7. The cable testing system of claim 1, further comprising:
a first jack including a first set of wire pairs; and
an adapter connector including a plurality of connector pins, wherein each connector pin of the plurality of connector pins is coupled by a different signal path of the plurality of signal paths to a different wire pair of the first set of wire pairs.

8. The cable testing system of claim 7, further comprising:
a second jack including a second set of wire pairs, wherein each connector pin of the plurality of connector pins is coupled by a different signal path of the plurality of signal paths to a different wire pair of the second set of wire pairs.

9. The cable testing system of claim 7,
wherein a first connector pin of the plurality of connector pins is coupled by a first signal path of the plurality of signal paths to a first wire pair of the first set of wire pairs; and
wherein the activated state of the first signal path includes a multi-cable testing mode and an alien cross-talking testing mode.

10. The cable testing system of claim 9, wherein the alien cross-talking testing mode of the activated state includes a test signal transmission mode and a test signal reception mode.

11. A multi-jack cable adapter, comprising:
a switch matrix operable to be in electrical communication with a cable tester and a plurality of cables to establish a plurality of signal paths between the cable tester and the plurality of cables; and
a switch controller operable to be in electrical communication with the switch matrix and the cable tester to control a switching by the switch matrix of each signal path between an activated state and a deactivated state as commanded by the cable tester.

12. The multi-jack cable adapter of claim 11, wherein the activated state of a first signal path of the plurality of signal paths includes a multi-cable testing mode and an alien cross-talking testing mode.

13. The multi-jack cable adapter of claim 12, wherein the alien cross-talking testing mode of the activated state includes a test signal transmission mode and a test signal reception mode.

14. The multi-jack cable adapter of claim 11, wherein the deactivated state of a first signal path of the plurality of signal paths includes a test signal termination mode.

15. The multi-jack cable adapter of claim 11,
wherein the activated state of a first signal path of the plurality of signal paths includes a multi-cable testing mode and an alien cross-talking testing mode;
wherein the deactivated state of the first signal path includes a test signal termination mode; and
wherein the switch matrix includes a first switch layer operable to switch the first signal path among the multi-cable testing mode, the alien cross-talk testing mode and the test signal termination mode.

16. The multi-jack cable adapter of claim 15,
wherein the alien cross-talking testing mode of the activated state includes a test signal transmission mode and a test signal reception mode; and
wherein the switch matrix further includes a second switch layer operable to switch the first signal path between the test signal transmission mode and the test signal reception mode in response to the first signal path being switched to the alien cross-talk testing mode by the first switch layer.

17. The multi-jack cable adapter of claim 11, further comprising:
a first jack including a first set of wire pairs; and
an adapter connector including a plurality of connector pins, wherein each connector pin of the plurality of connector pins is coupled by a different signal path of the plurality of signal paths to a different wire pair of the first set of wire pairs.

18. The multi-jack cable adapter of claim 17, further comprising:
a second jack including a second set of wire pairs, wherein each connector pin of the plurality of connector pins is coupled by a different signal path of the plurality of signal paths to a different wire pair of the second set of wire pairs.

19. The multi-jack cable adapter of claim 17,
wherein a first connector pin of the plurality of connector pins is coupled by a first signal path of the plurality of signal paths to a first wire pair of the first set of wire pairs; and
wherein the activated state of the first signal path includes a multi-cable testing mode and an alien cross-talking testing mode.

20. The multi-jack cable adapter of claim 19, wherein the alien cross-talking testing mode of the activated state includes a test signal transmission mode and a test signal reception mode.

21. A cable testing method, comprising:
providing a switch matrix establishing a plurality of signal paths between a cable tester and a plurality of cables; and
controlling a switching of each signal path by the switch matrix between an activated state and a deactivated state as commanded by the cable tester.
